(19) United States
(12) Patent Application Publication
(10) Pub. No.: US 2024/0349573 A1
(43) Pub. Date: Oct. 17, 2024

(54) ELECTRONIC DEVICE

(71) Applicants: Samsung Display Co., Ltd., Yongin-si (KR); Postech Research and Business Development Foundation, Pohang-si (KR)

(72) Inventors: KUNWOOK CHO, Yongin-si (KR); Kyu Min SIM, Pohang-si (KR); Dae Sung CHUNG, Pohang-si (KR); SEOKGYU YOON, Yongin-si (KR)

(73) Assignees: Samsung Display Co., Ltd., Yongin-si (KR); Postech Research and Business Development Foundation, Pohang-si (KR)

(21) Appl. No.: 18/636,536

(22) Filed: Apr. 16, 2024

(30) Foreign Application Priority Data
Apr. 17, 2023 (KR) 10-2023-0050298

(51) Int. Cl. H10K 59/65; H10K 59/122; H10K 59/40; H10K 85/60; H10K 101/30

(52) U.S. Cl. CPC H10K 59/65; H10K 59/122; H10K 59/40; H10K 85/615; H10K 85/654; H10K 85/6572; H10K 85/6574; H10K 2101/30

(57) ABSTRACT

Embodiments provide an electronic device that includes a display element layer disposed on a base layer and including at least one light sensing element. The light sensing element includes a first electrode, a hole transport region disposed on the first electrode, a photoelectric conversion layer disposed on the hole transport region, an electron transport region disposed on the photoelectric conversion layer, and a second electrode disposed on the electron transport region, wherein the second electrode comprises a metal and an organic compound, and a doping concentration of the organic compound is in a range of about 0.5% to about 10%.

### CROSS-REFERENCE TO RELATED APPLICATION(S)

This application claims priority to and benefits of Korean Patent Application No. 10-2023-0050298 under 35 U.S.C. § 119, filed on Apr. 17, 2023 in the Korean Intellectual Property Office, the entire contents of which are incorporated herein by reference.

### BACKGROUND

### 1. Technical Field

The disclosure relates to an electronic device including a light sensing element.

### 2. Description of the Related Art

Various forms of electronic devices may be used in order to provide image information. Electronic devices provide various functions enabling communication with a user, such as detection of an input from a user. Electronic devices may also include a function for detecting an external input.

An external input recognition method may include a capacitive method of sensing a variation in capacitance between electrodes, a light sensing method of sensing incident light by using a light sensor, and an ultrasonic method of sensing a vibration by using a piezoelectric body.

For example, when the electronic device includes a light sensitive sensor, there may be a need to increase the efficiency of converting received light to electric signals in order to improve the sensitivity of the light sensing sensor.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide an electronic device including a light sensing element having improved efficiency.

An embodiment provides an electronic device which may include a display element layer disposed on a base layer and including at least one light sensing element. The light sensing element may include a first electrode, a hole transport region disposed on the first electrode, a photoelectric conversion layer disposed on the hole transport region, an electron transport region disposed on the photoelectric conversion layer, and a second electrode disposed on the electron transport region. The second electrode may include a metal and an organic compound, and a doping concentration of the organic compound may be in a range of about 0.5% to about 10%.

In an embodiment, the metal may have a work function greater than or equal to about 3.0 eV.

In an embodiment, the metal may include at least one of Ca, Mg, Al, Ag, Au, Zn, and Cu.

In an embodiment, the organic compound may have a lowest unoccupied molecular orbital (LUMO) energy level in a range of about 2.0 eV to about 3.0 eV.

In an embodiment, the organic compound may include at least one of a triazine-based compound, a phosphine oxide-based compound, and a phenanthroline-based compound.

In an embodiment, the organic compound may include at least one compound selected from Compound Group 1, which is explained below.

In an embodiment, the photoelectric conversion layer may include at least one of an electron donor compound and an electron acceptor compound.

In an embodiment, the photoelectric conversion layer may include a first sub-photoelectric conversion layer including the electron donor compound, and a second sub-photoelectric conversion layer disposed on the first sub-photoelectric conversion layer and including the electron acceptor compound.

In an embodiment, the photoelectric conversion layer may include the electron donor compound and the electron acceptor compound.

In an embodiment, the photoelectric conversion layer may include a first sub-photoelectric conversion layer including the electron donor compound, a third sub-photoelectric conversion layer disposed on the first sub-photoelectric conversion layer and including the electron donor compound and the electron acceptor compound, and a second sub-photoelectric conversion layer on the third sub-photoelectric conversion layer and including the electron acceptor compound.

In an embodiment, the hole transport region may include at least one of a hole injection layer, a hole transport layer, and an electron blocking layer.

In an embodiment, the electron transport region may include at least one of a hole blocking layer, an electron transport layer, and an electron injection layer.

In an embodiment, an electronic device may include a display element layer disposed on a base layer. The display element layer may include a pixel defining film in which an opening is defined, a light emitting element, and a light sensing element, wherein the light emitting element and the light sensing element may each be divided by the pixel defining film. The light emitting element and the light sensing element may each include a first electrode, a hole transport region disposed on the first electrode, an electron transport region disposed on the hole transport region, and a second electrode disposed on the electron transport region and including a metal nanostructure and an organic compound, wherein a doping concentration of the organic compound may be in a range of about 0.5% to about 10%.

In an embodiment, the metal nanostructure may be in a form of a nanowire in which metal nanoparticles are connected.

In an embodiment, the metal nanoparticles may have a work function greater than or equal to about 3.0 eV.

In an embodiment, the metal nanostructure may include at least one of Ca, Mg, Al, Ag, Au, Zn, and Cu.

In an embodiment, the organic compound may have a lowest unoccupied molecular orbital (LUMO) energy level in a range of about 2.0 eV to about 3.0 eV.

In an embodiment, the organic compound may include at least one of a triazine-based compound, a phosphine oxide-based compound, and a phenanthroline-based compound.

In an embodiment, the light emitting element may include an emission layer disposed between the hole transport region and the electron transport region, the light sensing element may include a photoelectric conversion layer disposed between the hole transport region and the electron transport region, and the photoelectric conversion layer may convert incident light to an electrical signal.

In an embodiment, the photoelectric conversion layer may include at least one of an electron donor compound and an electron acceptor compound.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic perspective view of an electronic device according to an embodiment;

FIG. 2 is an exploded schematic perspective view of the electronic device according to an embodiment;

FIG. 3 is a schematic cross-sectional view of the electronic device according to an embodiment;

FIG. 4 is an enlarged schematic plan view of a partial region of a display module according to an embodiment;

FIG. 5 is a schematic cross-sectional view of a portion of the display module according to an embodiment;

FIG. 6 is a schematic cross-sectional view of a portion of the electronic device according to an embodiment;

FIG. 7A is a schematic cross-sectional view of a light emitting element according to an embodiment;

FIGS. 7B to 7D are each a schematic cross-sectional view of a light sensing element according to an embodiment;

FIG. 8A is a schematic perspective view of a second electrode according to an embodiment of the inventive concept;

FIG. 8B is a schematic cross-sectional view of the second electrode according to the embodiment;

FIG. 9 is a graph showing the evaluation results of transmittance and sheet resistance of the light sensing element according to an embodiment; and

FIG. 10 is a graph showing the efficiency of the light sensing elements of the Examples and Comparative Examples.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within +20%, +10%, or +5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amine group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted at an atom which is substituted with a corresponding substituent, or as a substituent that is sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, but may be 2 to 30, 2 to 20, or 2 to 10. Examples of an alkenyl group may include a vinyl group, a 1-butenyl group, a 1-pentenyl group, a 1,3-butadienyl group, a styrenyl group, a styryl vinyl group, etc., but embodiments are not limited thereto.

In the specification, an alkynyl group may be a hydrocarbon group that includes one or more carbon-carbon triple bonds in the middle or at a terminus of an alkyl group having 2 or more carbon atoms. An alkynyl group may be linear or branched. The number of carbon atoms in an alkynyl group is not particularly limited, but may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

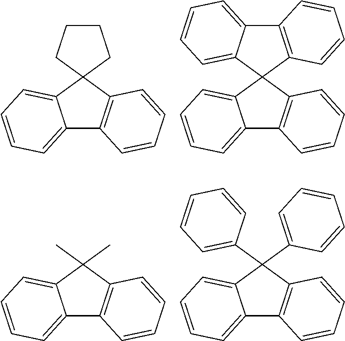

In the specification, a heterocyclic group may be any functional group or substituent derived from a ring that includes at least one of B, O, N, P, Si, S, and Se as a heteroatom. A heterocyclic group may be aliphatic or aromatic. An aromatic heterocyclic group may be a heteroaryl group. An aliphatic heterocycle and an aromatic heterocycle may each independently be monocyclic or polycyclic.

In the specification, a heterocyclic group may include at least one of B, O, N, P, Si, Se, and S as a heteroatom. If a heterocyclic group includes two or more heteroatoms, the two or more heteroatoms may be the same as or different from each other. A heterocyclic group may be monocyclic or polycyclic. A heterocyclic group may be a heteroaryl group. The number of ring-forming carbon atoms in a heterocyclic group may be 2 to 30, 2 to 20, or 2 to 10.

In the specification, an aliphatic heterocyclic group may include at least one of B, O, N, P, Si, Se, and S as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may contain at least one of B, O, N, P, Si, Se, and S as a heteroatom. If a heteroaryl group includes two or more heteroatoms, the two or more heteroatoms may be the same as or different from each other. A heteroaryl group may be monocyclic or polycyclic. The number of ring-forming carbon atoms in a heteroaryl group may be 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. The alkyl group in an alkylsilyl group may be linear, branched, or cyclic. The number of carbon atoms in an alkylsilyl group is not particularly limited, but may be, for example, 1 to 20 or 1 to 10. The number of carbon atoms in the arylsilyl group is not particularly limited, but may be, for example, 6 to 30, 6 to 20, or 6 to 15. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, but may be 1 to 40, 1 to 30, or 1 to 20. For example, a carbonyl group may have one of the following structures, but embodiments are not limited thereto.

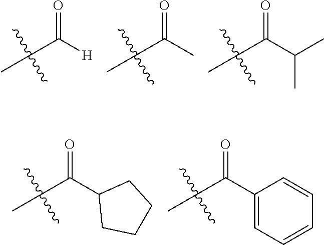

In the specification, the number of carbon atoms in an amino group is not particularly limited, and may be, for example, 1 to 30. An amino group may be an alkyl amino group, an aryl amino group, or a heteroaryl amino group. Examples of an amino group may include a methylamino group, a dimethylamino group, a phenylamino group, a diphenylamino group, a naphthylamino group, a 9-methyl-anthracenylamino group, etc., but embodiments are not limited thereto.

In the specification, a phosphine oxide group may be an alkyl group or an aryl group as defined herein that is combined with an —P(═O)—. The number of carbon atoms in a phosphine oxide group is not particularly limited, but may be 1 to 30, 1 to 20, or 1 to 10. A phosphine oxide group may be an alkyl phosphine oxide group or an aryl phosphine oxide group. For example, a phosphine oxide group may have a structure as shown below, but embodiments are not limited thereto.

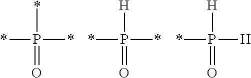

In the specification, a phosphine sulfide group may be an alkyl group or an aryl group as defined herein that is combined with —P(═S)—. The number of carbon atoms in a phosphine sulfide group is not particularly limited, but may be 1 to 30, 1 to 20, or 1 to 10. A phosphine sulfide group may be an alkyl phosphine sulfide group or an aryl phosphine sulfide group. For example, a phosphine sulfide group may have a structure as shown below, but embodiments are not limited thereto.

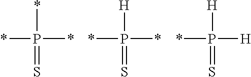

In the specification, the number of carbon atoms in a sulfinyl group or a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not particularly limited, but may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. The number of carbon atoms in a boron group is not particularly limited but may be, for example, 1 to 30, 1 to 20, or 1 to 10. Examples of a boron group may include a dimethylboron group, a t-butylmethylboron group, a diphenylboron group, a phenylboron group, etc., but embodiments are not limited thereto.

In the specification, the number of carbon atoms in an amine group is not particularly limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, a triphenylamine group, etc., but embodiments are not limited thereto.

In the specification, an alkyl group within an alkoxy group, an alkylthio group, an alkylsulfoxy group, an alkylsulfoxy group, an alkylaryl group, an alkylamino group, an alkyl boron group, an alkyl silyl group, an alkyl phosphine oxide group, an alkyl phosphine sulfide group, or an alkyl amine group may be the same as an example of an alkyl group as described above.

In the specification, an aryl group within an aryloxy group, an arylthio group, an arylsulfoxy group, an arylsulfonyl group, an arylamino group, an arylboron group, an arylsilyl group, an aryl phosphine oxide group, an aryl phosphine sulfide group, or an arylamine group may be the same as an example of an aryl group as described above.

In the specification, a direct linkage may be a single bond.

In the specification, the symbols [symbol] and [symbol] each represent a bond to a neighboring atom in a corresponding formula or moiety.

Hereinafter, embodiments will be described with reference to the accompanying drawings.

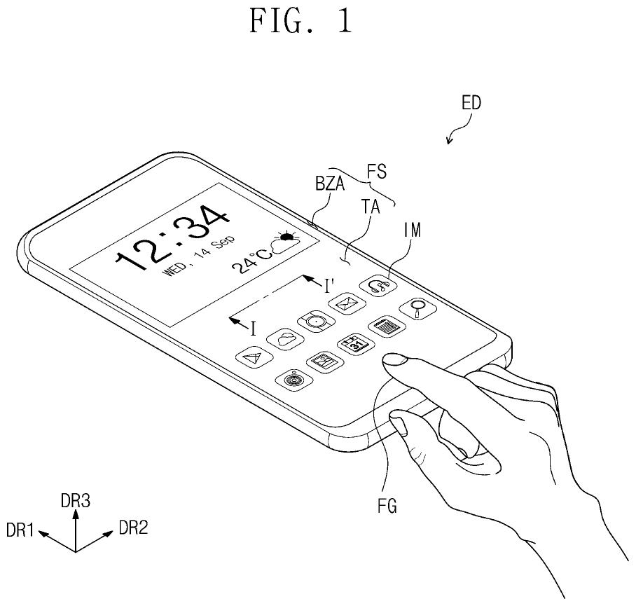

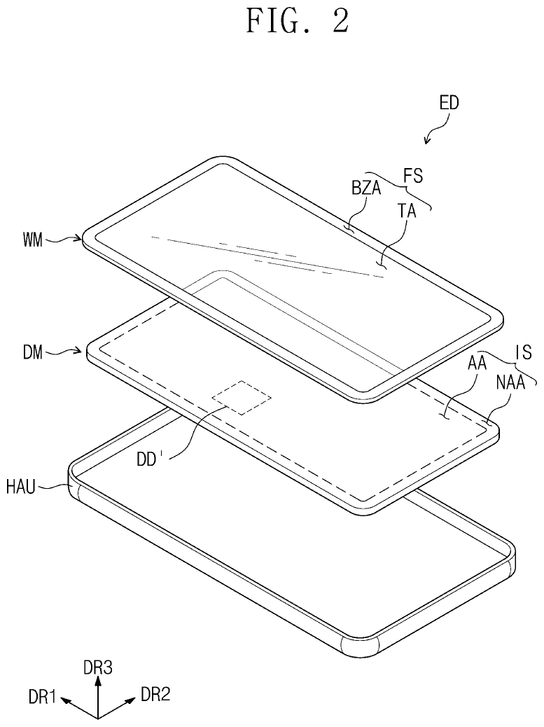

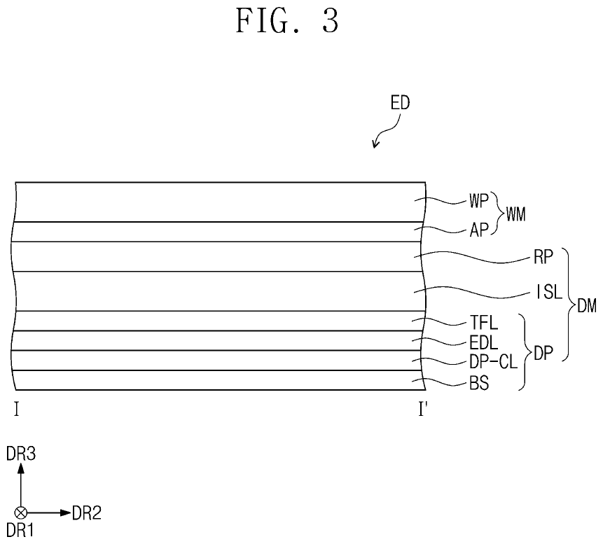

FIG. 1 is a schematic perspective view of an electronic device according to an embodiment. FIG. 2 is an exploded schematic perspective view of the electronic device according to an embodiment. FIG. 3 is a schematic cross-sectional view of the electronic device according to an embodiment, and corresponding to a portion taken along line I-I′ of FIG. 1.

Referring to FIGS. 1 to 3, the electronic device ED according to an embodiment may have a rectangular shape having longer sides that are parallel to a first direction DR1 and having shorter sides that are parallel to a second direction DR2 crossing the first direction DR1. However, embodiments are not limited thereto, and the electronic device ED may have various shapes such as a circle or a polygon.

The electronic device ED may be activated according to an electrical signal. For example, the electronic device ED may be a mobile phone, a tablet, a car navigation device, a game console, or a wearable device, but embodiments are not limited thereto. FIG. 1 illustrates that the electronic device ED is a mobile phone for convenience of explanation.

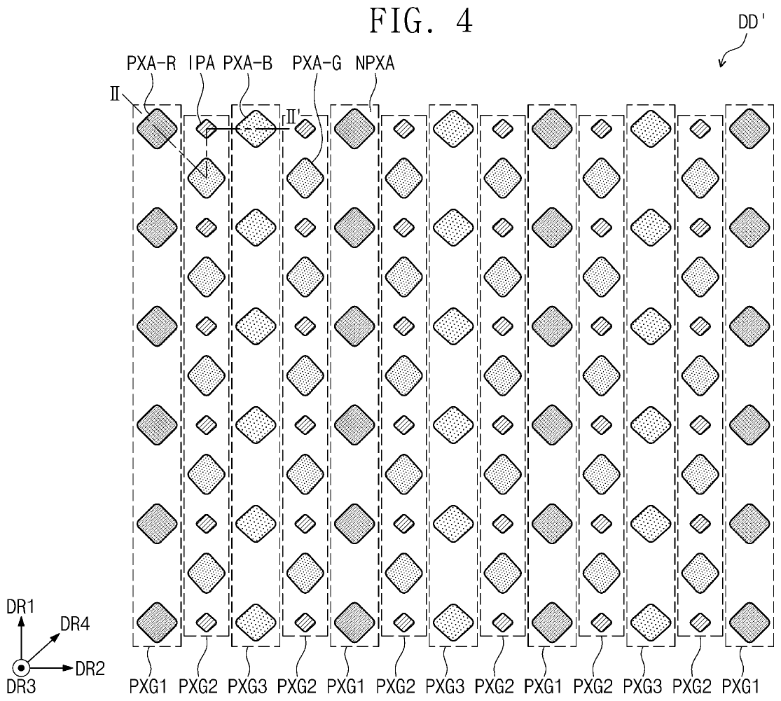

Hereinafter, a third direction DR3 may be defined as a normal direction that is substantially perpendicular to the plane defined by the first direction DR1 and the second direction DR2. In this specification, the term “in a plan view” may be interpreted as a case of viewing in the third direction DR3. A fourth direction DR4 (FIG. 4) may be a direction between the first direction DR1 and the second direction DR2. The first to fourth directions DR1, DR2, DR3, and DR4 as described in the specification are relative concepts, and may thus be changed to other directions.

The electronic device ED may have a thickness direction parallel to the third direction DR3, which may be a normal direction to the plane defined by the first direction DR1 and the second direction DR2. In this specification, a front surface (or top surface) and a rear surface (or bottom surface) of members of the electronic device ED may be defined on the basis of the third direction DR3.

The electronic device ED may be rigid or flexible. In the specification, the term “flexible” may describe a characteristic capable of being curved, and may include all structures from being fully bent to being bent in a scale of several nanometers. For example, a flexible electronic device ED may be a curved device, a foldable device, or a rollable device.

The electronic device ED may display an image IM on a display surface FS parallel to each of the first direction DR1 and the second direction DR2. The image IM may include a still image as well as a dynamic image. FIG. 1 illustrates a window that shows the time and icons as examples of the image IM.

The display surface FS of the electronic device ED may further include a curved surface that is bent from at least one side of the plane defined by the first direction DR1 and the second direction DR2. For example, the display surface FS may include only the plane. As another example, the display surface FS may further include at least one curved surface, such as four curved surfaces that are respectively bent from four sides. The display surface FS may correspond to a front surface of the electronic device ED, which may correspond to a front surface FS of a window member WM. Hereinafter, the display surface FS of the electronic device ED and the front surface FS of the window member WM may be indicated by the same reference symbol.

The electronic device ED according to an embodiment may sense a user's input applied from the outside. The user's input may include external inputs applied when approaching the electronic device ED or being adjacent by a preset distance (e.g., hovering), as well as contact by a part of a body such as a user's hand or a separate device (e.g., an active pen or a digitizer). The external inputs may have various forms such as force, pressure, temperature, and light.

The electronic device ED according to an embodiment may detect the user's input through the display surface FS defined in the front surface, and may respond to the sensed input signal. However, the region of the electronic device ED which senses the external inputs is not limited to the front surface of the electronic device ED, and may vary with the design of the electronic device ED. For example, the electronic device ED may sense the user's input applied to a side surface or a rear surface of the electronic device ED.

For example, the electronic device ED may sense biometric information, such as a fingerprint FG of a user, applied from the outside. A biometric information sensing region capable of sensing the biometric information of the user may be provided to the display surface FS of the electronic device ED. The biometric information sensing region may be provided to the whole region of the display surface FS or a partial region of the display surface FS.

The electronic device ED may include a window member WM, a display module DM, and a housing HAU. In an embodiment, the window member WM and the housing HAU may be combined to form the exterior of the electronic device ED.

The window member WM may be disposed on the display module DM. The window member WM may include a window WP and an adhesive layer AP, and the adhesive layer AP may be disposed between the display module DM and the window WP. The adhesive layer AP may be an optically clear adhesive (OCA) film or an optically clear adhesive resin (OCR) film. In an embodiment, the adhesive layer AP may be omitted.

The window WP may cover the entire exterior of the display module DM. The window WP may have a shape corresponding to the shape of the display module DM. In the electronic device ED according to an embodiment, the window WP may include an optically clear insulating material. For example, the window WP may include a glass or a synthetic resin as a base film. The window WP may have a single-layer structure or a multi-layer structure. For example, the window WP may include plastic films which are bonded through an adhesive, or may include a glass film and plastic films which are bonded through an adhesive. The window WP may further include functional layers, such as an anti-fingerprint layer, a phase control layer, and a hard coating layer, which may be disposed on a clear film. The window WP may correspond to the uppermost layer of the electronic device ED.

The front surface FS of the window member WM may correspond to the front surface of the electronic device ED. The front surface FS of the window member WM may include a transmission region TA and a bezel region BZA.

The transmission region TA may be an optically clear region. The transmission region TA may transmit the image IM provided by the display module DM. In an embodiment, the transmission region TA is illustrated as a rectangular shape, but may have various shapes and is not limited to any particular embodiment.

The bezel region BZA may have a light transmittance that is lower than the light transmittance of the transmission region TA. The bezel region BZA may correspond to a region in which a material having a color (e.g., a predetermined color or a selectable color) is printed. The bezel region BZA may prevent the transmission of light, thereby preventing a component of the display module DM that overlaps the bezel region BZA from being viewed from the outside.

The bezel region BZA may be adjacent to the transmission region TA. A shape of the transmission region TA may be defined substantially by the bezel region BZA. For example, the bezel region BZA may be disposed outside the transmission region TA, and may surround the transmission region TA. However, this is merely illustrative. For example, the bezel region BZA may be disposed to be adjacent to only one side of the transmission region TA, or may be disposed in a side surface of the electronic device ED rather than the front surface. In an embodiment, the bezel region BZA may be omitted.

The display module DM may be disposed between the window member WM and the housing HAU. The display module DM may display the image IM and may sense an external input. The image IM may be displayed on the front surface IS of the display module DM. The front surface IS of the display module DM may include an active region AA and a peripheral region NAA.

The active region AA may be a region that is activated according to an electrical signal. The active region AA may be a region in which the image IM is displayed. In an embodiment, the active region AA may be a region in which the external input is sensed. The active region AA may overlap at least a portion of the transmission region TA. Accordingly, the user may view the image IM displayed in the active region AA through the transmission region TA.

The peripheral region NAA may be adjacent to at least one side of the active region AA. For example, the peripheral region NAA may surround the active region AA. However, embodiments are not limited thereto. In an embodiment, a part of the peripheral region NAA may be omitted. A circuit or a wiring for driving the active region AA may be disposed in the peripheral region NAA. The peripheral region NAA may overlap at least a portion of the bezel region BZA, and the bezel region BZA may prevent the components that are disposed in the peripheral region NAA from being viewed from the outside.

The display module DM may include a display panel DP and an input sensing layer ISL. The display panel DP may display the image according to an electrical signal, and the input sensing layer ISL may sense an external input applied from the outside. The external input may be provided in various forms as described above.

The display panel DP according to an embodiment may be a light emitting display panel. However, embodiments are not particularly limited thereto. For example, the display panel DP may be an organic light emitting display panel, an inorganic light emitting display panel, or a quantum dot light emitting display panel. An emission layer of the organic light emitting display panel may include an organic light emitting material, and an emission layer of the inorganic light emitting display panel may include an inorganic light emitting material. An emission layer of the quantum dot light emitting display panel may include a quantum dot, a quantum rod, etc. Hereinafter, the display panel DP will be described as the organic light emitting display panel.

The display panel DP may include a base layer BS, a circuit layer DP-CL, a display element layer EDL, and an encapsulation layer TFL. The display panel DP may be a flexible display panel. However, embodiments are not limited thereto. For example, the display panel DP may be a foldable display panel that is capable of folding with respect to a folding axis, or the display panel DP may be a rigid display panel.

The input sensing layer ISL may be disposed on the display panel DP. The input sensing layer ISL may be directly disposed on the encapsulation layer TFL. According to an embodiment, the input sensing layer ISL may be provided on the display panel DP through a continuous process. For example, when the input sensing layer ISL is directly disposed on the display panel DP, an adhesive film may not be disposed between the input sensing layer ISL and the encapsulation layer TFL. As another example, an adhesive film may be disposed between the input sensing layer ISL and the display panel DP. In case that an adhesive film is disposed between the input sensing layer ISL and the display panel DP, the input sensing layer ISL may be manufactured through a separate process from the display panel DP instead of being manufactured by a continuous process with the display panel DP, and the input sensing layer ISL may be fixed to a top surface of the display panel DP by the adhesive film.

The input sensing layer ISL may sense an external input (e.g., the user's touch), convert the external input to an input signal (e.g., a predetermined input signal or a selectable input signal), and provide the input signal to the display panel DP. The input sensing layer ISL may include multiple sensing electrodes so as to sense an external input. The sensing electrodes may sense an external input in a capacitive method. The display panel DP may receive an input signal from the input sensing layer ISL, and generate an image corresponding to the input signal.

The display module DM may further include an anti-reflection member RP. The anti-reflection member RP may include a color filter layer or a polarizing layer. For example, the anti-reflection member RP may reduce the reflectance of an external light that is incident from the outside, or may absorb and block a portion of an external light that is incident from the outside.

The housing HAU may be coupled to the window member WM. The housing HAU may be coupled to the window member WM to provide an internal space. The display module DM may be accommodated in the internal space. The housing HAU may include a material having a relatively high rigidity. For example, the housing HAU may include glass, plastic, or metal, or the housing HAU may include frames and/or plates made of a combination of glass, plastic, and metal. The housing HAU may stably protect the components of the display module DM accommodated in the internal space from external impact. Although not illustrated, a battery module for supplying operational power for the electronic device ED may be disposed between the display module DM and the housing HAU.

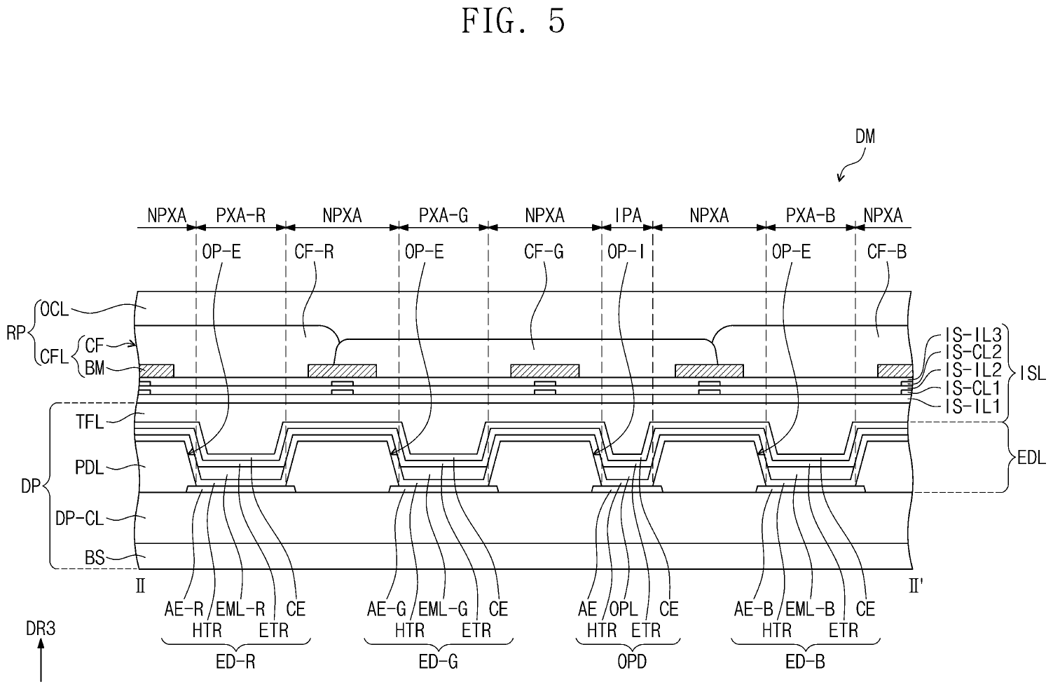

FIG. 4 is an enlarged schematic plan view of a partial region of a display module according to an embodiment. FIG. 5 is a schematic cross-sectional view of a portion of the display module according to an embodiment. FIG. 4 is a schematic plan view illustrating the DD′ region of FIG. 2, and FIG. 5 is a schematic cross-sectional view illustrating a part taken along line II-II′ of FIG. 4. FIG. 5 illustrates light emitting regions PXA-R, PXA-G, and PXA-B and a portion of the light sensing region IPA as illustrated in FIG. 4.

Referring to FIGS. 4 and 5, the display module DM may include a non-light emitting region NPXA, light emitting regions PXA-R, PXA-G, and PXA-B, and light sensing regions IPA. The light emitting regions PXA-R, PXA-G, and PXA-B may each be a region that emits light respectively generated from light emitting elements ED-R, ED-G, and ED-B. The light emitting regions PXA-R, PXA-G, and PXA-B may be spaced apart from each other in a plan view. The light sensing regions IPA may each be a region that receives and senses the incident light reflected from an external object. The light emitting regions PXA-R, PXA-G, and PXA-B and the light sensing regions IPA may each be a region separated by a pixel defining film PDL. The non-light emitting regions NPXA may be regions between the neighboring light emitting regions PXA-R, PXA-G, and PXA-B and between the light sensing regions IPA and the light emitting regions PXA-R, PXA-G, and PXA-B. The light emitting regions PXA-R, PXA-G, and PXA-B, and the light sensing regions IPA may be distinguished from one another by the non-light emitting regions NPXA. The non-light emitting regions NPXA may surround each of the light emitting regions PXA-R, PXA-G, and PXA-B, and the light sensing regions IPA. The non-light emitting regions NPXA may be regions corresponding to the pixel defining film PDL. The pixel defining film PDL may separate the light emitting elements ED-R, ED-G, and ED-B and the light sensing element OPD from each other. The emission layers EML-R, EML-G, and EML-B of the light emitting elements ED-R, ED-G, and ED-B and a photoelectric conversion layer OPL of the light sensing element OPD may be disposed in openings OP-E and OP-I defined in the pixel defining film PDL and separated from each other.

The light emitting regions PXA-R, PXA-G, and PXA-B may be divided into groups according to colors of light generated from the light emitting elements ED-R, ED-G, and ED-B. FIGS. 4 and 5 illustrate, as an example, three light emitting regions PXA-R, PXA-G, and PXA-B, which respectively emit red light, green light, and blue light. For example, the display module DM according to an embodiment may include the red light emitting region PXA-R that emits red light, the green light emitting region PXA-G that emits green light, and the blue light emitting region PXA-B that emits blue light.

The light emitting elements ED-R, ED-G, and ED-B in the display module DM according to an embodiment may emit light according to an electrical signal. The light emitting elements ED-R, ED-G, and ED-B may each emit light in different wavelength regions. For example, the display module DM according to an embodiment may include a first light emitting element ED-R that emits red light, a second light emitting element ED-G that emits green light, and a third light emitting element ED-B that emits blue light. However, embodiments are not limited thereto, and the first to third light emitting elements ED-R, ED-G, and ED-B may emit light having a same wavelength region or may emit light having at least one different wavelength region. For example, the first to third light emitting elements ED-R, ED-G, and ED-B may all emit blue light.

The light sensing element OPD may receive a light signal and convert it to an electrical signal. For example, the light sensing element OPD may be a light sensor for sensing the light that is incident to the light sensing element OPD and converting the light signal to the electrical signal. As an example, the light sensing element OPD may be an organic photo diode including an organic material.

FIGS. 4 and 5 illustrate that the light emitting regions PXA-R, PXA-G, and PXA-B all have a similar area, but embodiments are not limited thereto. For example, the areas of the light emitting regions PXA-R, PXA-G, and PXA-B may be different in size or shape from each other according to a wavelength region of emitted light. In an embodiment, the areas of the light emitting regions PXA-R, PXA-G, and PXA-B may be areas in a plan view that are defined by the first direction DR1 and the second direction DR2. In embodiments, the light emitting regions PXA-R, PXA-G, and PXA-B may emit light having colors that are different from the red light, green light, and blue light as described above, or the light emitting regions PXA-R, PXA-G, and PXA-B may have a shape that is different in a plan to what is illustrated.

In an embodiment, an area of the light sensing region IPA in a plan view may be smaller than an area of each of the red light emitting region PXA-R, the blue light emitting region PXA-B, and the green light emitting region PXA-G. However, embodiments are not limited thereto, and the area of the light sensing region IPA may be the same size as or a larger size than that of one of the red light emitting region PXA-R, the blue light emitting region PXA-B, or the green light emitting region PXA-G.

Referring to FIG. 4, the red light emitting regions PXA-R may be arranged to be spaced apart in the first direction DR1 to constitute a first group PXG1. The green light emitting regions PXA-G may be arranged alternately with the light sensing region IPA in the first direction DR1 to constitute a second group PXG2. The blue light emitting regions PXA-B may be arranged to be spaced apart in the first direction DR1 to constitute a third group PXG3.

The first group PXG1 to the third group PXG3 may be arranged in the second direction DR2. Multiples of each of the first group PXG1 to the third group PXG3 may be provided. In an embodiment illustrated in FIG. 4, the first group PXG1, the second group PXG2, the third group PXG3, and the second group PXG2 form one repeating unit in the second direction DR2, and the repeating units may be repeatedly arranged in the second direction DR2.

In an embodiment, a green light emitting region PXA-G may be disposed to be spaced apart from a red light emitting region PXA-R and a blue light emitting region PXA-B in the fourth direction DR4. The fourth direction DR4 may be a direction between the first direction DR1 and the second direction DR2.

In an embodiment, the light sensing region IPA may be spaced apart from each of the light emitting regions PXA-R, PXA-G, and PXA-B, and may be disposed to be spaced apart in the second direction DR2 between the red light emitting region PXA-R and the blue light emitting region PXA-B. The light sensing region IPA and the green light emitting region PXA-G may be alternately disposed in the first direction DR1.

The arrangement structure of the light emitting regions PXA-R, PXA-G, and PXA-B illustrated in FIG. 4 may be referred to as a PenTile® structure. However, the arrangement structure of the light emitting regions PXA-R, PXA-G, and PXA-B in the electronic device ED according to an embodiment is not limited to the arrangement structure illustrated in FIG. 4. For example, in an embodiment, the light emitting regions PXA-R, PXA-G, and PXA-B may have a stripe arrangement structure in which the red light emitting region PXA-R, the green light emitting region PXA-G, and the blue light emitting region PXA-B are alternately arranged in the first direction DR1 or the second direction DR2. In the stripe arrangement structure, the light sensing region IPA may form a same line or a same row as the green light emitting region PXA-G to form a single stripe arrangement. However, in an embodiment, the arrangement form, the arrangement ratio, or the like of the light sensing region IPA and the light emitting regions PXA-R, PXA-G, and PXA-B may be different from those described above.

Referring to FIG. 5, the display module DM according to an embodiment may include a display panel DP, an input sensing layer ISL, and an anti-reflection member RP.

The display panel DP may include a base layer BS. The base layer BS may provide a base surface on which the display element layer EDL is disposed. The base layer BS may include a synthetic resin layer. The synthetic resin layer may be a polyimide-based resin layer, and the material thereof is not particularly limited. In an embodiment, the base layer BS may include a glass substrate, a metal substrate, an organic/inorganic composite material substrate, or the like.

The base layer BS may have a multi-layered structure. For example, the base layer BS may have a three-layered structure constituted by a synthetic resin layer, an adhesive layer, and a synthetic resin layer. The synthetic resin layer may include a polyimide-based resin. The synthetic resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. In this specification, the term “x-based” resin represents a feature of including a functional group of “x”.

A circuit layer DP-CL is disposed on the base layer BS. The circuit layer DP-CL may include an insulation layer, a semiconductor pattern, a conductive pattern, a signal line, etc. The insulation layer, the semiconductor layer, and the conductive layer may be formed on the base layer BS through a process such as coating or vapor deposition, and the insulation layer, the semiconductor layer, and the conductive layer may be patterned through photolithography processes. Thus, the semiconductor pattern, the conductive pattern, and the signal line, which are included in the circuit layer DP-CL, may be formed.

The display element layer EDL may be disposed on the circuit layer DP-CL. The display element layer EDL may include the light emitting elements ED-R, ED-G, and ED-B and the light sensing element OPD. For example, the light emitting elements ED-R, ED-G, and ED-B included in the display element layer EDL may include an organic light emitting element, a quantum dot light emitting element, a micro LED light emitting element, or a nano LED light emitting element. However, embodiments are not limited thereto, and the light emitting elements ED-R, ED-G, and ED-B may include various embodiments as long as light may be generated or the amount of light may be controlled according to an electrical signal. The light sensing element OPD may be a light sensor that receives and recognizes light reflected by an external object. For example, the light sensing element OPD may be a light sensor that recognizes light that is in a visible light region and reflected by an external object. In an embodiment, the light sensing element OPD may be a biometric sensor that recognizes light reflected from a portion of the user's body such as fingerprint or vein and converts the light signal to an electrical signal.

The display element layer EDL may include the pixel defining film PDL in which openings OP-E and OP-I are defined. The openings OP-E and OP-I of the pixel defining film PDL may define the light emitting regions PXA-R, PXA-G, and PXA-B and the light sensing region IPA. The light emitting elements ED-R, ED-G, and ED-B and the light sensing element OPD may be separated and divided on the basis of the pixel defining film PDL. First openings OP-E in which components of each of the light emitting elements ED-R, ED-G, and ED-B are disposed and a second opening OP-I in which component of the light sensing element OPD are disposed may be defined in the pixel defining film PDL.

The pixel defining film PDL may be disposed on the base layer BS. In an embodiment, the pixel defining film PDL may be disposed on the circuit layer DP-CL, and the openings OP-E and OP-I of the pixel defining film PDL may expose at least a portion of the first electrodes AE-R, AE-G, AE-B, and AE. In an embodiment, the light emitting regions PXA-R, PXA-G, and PXA-B and the light sensing region IPA may be defined to respectively correspond to the regions of the first electrodes AE-R, AE-G, AE-B, and AE that are exposed in the openings OP-E and OP-I.

In an embodiment, the pixel defining film PDL may be formed of a polymer resin. For example, the pixel defining film PDL may include a polyacrylate-based resin or a polyimide-based resin. In an embodiment, the pixel defining film PDL may further include an inorganic material in addition to the polymer resin. For example, the pixel defining films PDL may include a light absorbing material or a black pigment or a black dye. The pixel defining film PDL including the black pigment or the black dye may implement a black pixel defining film. In forming the pixel defining film PDL, carbon black, etc. may be used as the black pigment or the black dye, but embodiments are not limited thereto.

In an embodiment, the pixel defining film PDL may be formed of inorganic materials. For example, the pixel defining film PDL may be formed of silicon nitride (SiNₓ), silicon oxide (SiOₓ), silicon oxynitride (SiOₓN_{y}), etc.

In an embodiment, the light emitting elements ED-R, ED-G, and ED-B may respectively include the first electrodes AE-R, AE-G, and AE-B, may respectively include the emission layers EML-R, EML-G, and EML-B, and may include the second electrode CE. The light sensing element OPD may include the first electrode AE, the photoelectric conversion layer OPL, and the second electrode CE.

At least a portion of the first electrodes AE-R, AE-G, and AE-B of the light emitting elements ED-R, ED-G, and ED-B may be exposed in the first opening OP-E. In the specification, the first electrodes AE-R, AE-G, and AE-B constituting the light emitting elements ED-R, ED-G, and ED-B may be referred to as light emitting electrodes.

In an embodiment, the display element layer EDL may include a first light emitting element ED-R that is disposed to correspond to the red light emitting region PXA-R and emits red light, a second light emitting element ED-G that is disposed to correspond to the green light emitting region PXA-G and emits green light, and a third light emitting element ED-B that is disposed to correspond to the blue light emitting region PXA-B and emits blue light. The first light emitting element ED-R may include a first electrode AE-R, a second electrode CE facing the first electrode AE-R, and a red emission layer EML-R disposed between the first electrode AE-R and the second electrode CE. The second light emitting element ED-G may include a first electrode AE-G, a second electrode CE facing the first electrode AE-G, and a green emission layer EML-G disposed between the first electrode AE-G and the second electrode CE. The third light emitting element ED-B may include a first electrode AE-B, a second electrode CE facing the first electrode AE-B, and a blue emission layer EML-B disposed between the first electrode AE-B and the second electrode CE. The red emission layer EML-R, the green emission layer EML-G, and the blue emission layer EML-B may be disposed only in the corresponding region in the first opening OP-E.

At least a portion of the first electrode AE of the light sensing element OPD may be exposed in the second opening OP-I. The first electrode AE of the light sensing element OPD may be disposed on a same layer as the first electrodes AE-R, AE-G, and AE-B of the light emitting elements ED-R, ED-G, and ED-B. For example, the first electrode AE of the light sensing element OPD may be disposed on the circuit layer DP-CL, and may be formed through a same process with the first electrodes AE-R, AE-G, and AE-B of the light emitting elements ED-R, ED-G, and ED-B. In the specification, the first electrode AE constituting the light sensing element OPD may be a sensing electrode.

The light sensing element OPD may include a photoelectric conversion layer OPL disposed to correspond to the light sensing region IPA. The photoelectric conversion layer OPL may be a photoactive layer that converts incident light to an electrical signal. The light sensing element OPD may include the photoelectric conversion layer OPL, thereby separating the provided light into electrons and holes to transmit them to each electrode. The photoelectric conversion layer OPL may be disposed on the first electrode AE that is exposed by the second opening OP-I. The photoelectric conversion layer OPL may be disposed only in the region corresponding to the second opening OP-I. The second electrode CE may be disposed on the photoelectric conversion layer OPL. The second electrode CE disposed on the photoelectric conversion layer OPL may be formed through a same process with the second electrode CE disposed on the first light emitting element ED-R, the second light emitting element ED-G, and the third light emitting element ED-B. In an embodiment, the second electrode CE included in the light emitting elements ED-R, ED-G, and ED-B and the light sensing element OPD may have an integrated shape.

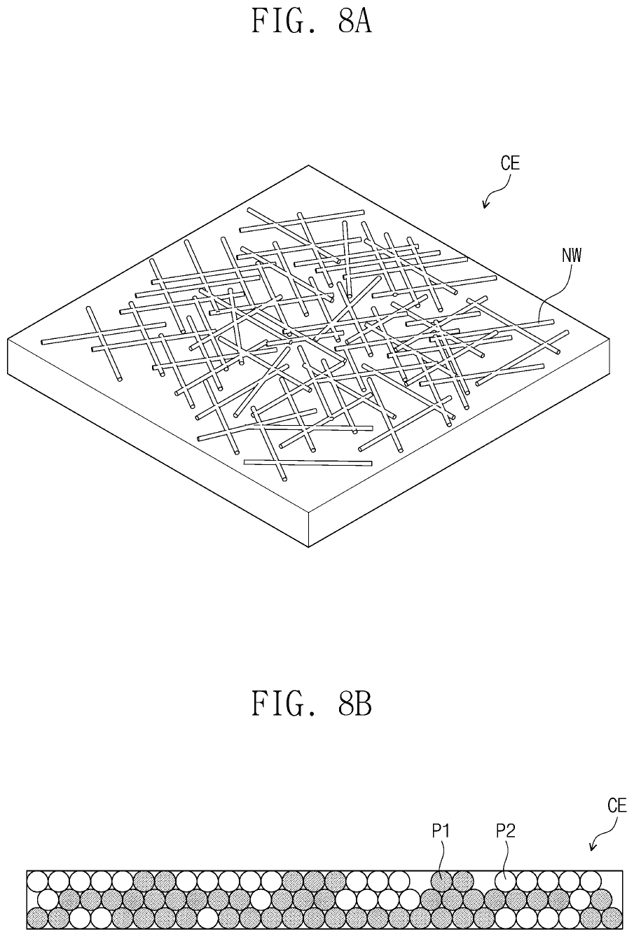

The electronic device ED according to an embodiment may include the light emitting elements ED-R, ED-G, and ED-B and the light sensing element OPD in the display element layer EDL, and the second electrode CE provided as a common layer to the light emitting elements ED-R, ED-G, and ED-B and the light sensing element OPD may include a metal and an organic compound that dopes the metal. Accordingly, in the electronic device ED according to an embodiment, extraction and injection of electrons in the light sensing element OPD may be facilitated. Accordingly, the electronic device ED according to an embodiment may exhibit improved light sensing element efficiency. The second electrode CE will be described later with reference to FIGS. 8A and 8B.

The light emitting elements ED-R, ED-G, and ED-B may include a hole transport region HTR disposed between the first electrodes AE-R, AE-G, and AE-B and the emission layers EML-R, EML-G, and EML-B, and may include an electron transport region ETR disposed between the emission layers EML-R, EML-G, and EML-B and the second electrode CE. The light sensing element OPD may include a hole transport region HTR disposed between the first electrode AE and the photoelectric conversion layer OPL, and may include an electron transport region ETR disposed between the photoelectric conversion layer OPL and the second electrode CE.

The hole transport region HTR may be commonly disposed in the light emitting regions PXA-R, PXA-G, and PXA-B and the non-light emitting region NPXA. The hole transport region HTR may be provided as a common layer, and may be commonly formed in the light emitting regions PXA-R, PXA-G, and PXA-B and the light sensing region IPA. For example, the hole transport region HTR may be commonly disposed on the first electrodes AE-R, AE-G, and AE-B of the light emitting elements ED-R, ED-G, and ED-B and the first electrode AE of the light sensing element OPD. The hole transport region HTR may include at least one of a hole transport layer, a hole injection layer, and an electron blocking layer.

The electron transport region ETR may be commonly disposed in the light emitting regions PXA-R, PXA-G, and PXA-B and the non-light emitting region NPXA. The electron transport region ETR may be provided as a common layer, and may be commonly formed in the light emitting regions PXA-R, PXA-G, and PXA-B, and the light sensing region IPA. For example, the electron transport region ETR may be commonly disposed on the emission layers EML-R, EML-G, and EML-B of the light emitting elements ED-R, ED-G, and ED-B and the photoelectric conversion layer OPL of the light sensing element OPD. For example, the electron transport region ETR may overlap the whole of the pixel defining film PDL, the emission layers EML-R, EML-G, and EML-B, and the photoelectric conversion layer OPL in a plan view. The electron transport region ETR may include at least one of an electron transport layer, an electron injection layer, and a hole blocking layer.

The display module DM according to an embodiment may include an encapsulation layer TFL disposed on the light emitting elements ED-R, ED-G, and ED-B and the light sensing element OPD. The encapsulation layer TFL seals the display element layer EDL. The encapsulation layer TFL may include at least one organic film and at least one inorganic film. The inorganic film may include an inorganic material and may protect the display element layer EDL from moisture and/or oxygen. The inorganic film may include, but is not particularly limited to, a silicon nitride layer, a silicon oxynitride layer, a silicon oxide layer, a titanium oxide layer, or an aluminum oxide layer. The organic layer may include an organic material and may protect the display element layer EDL from foreign substances such as dust particles.

The display module DM according to an embodiment may include the input sensing layer ISL disposed on the display panel DP. The input sensing layer ISL may be disposed on the display element layer EDL. The input sensing layer ISL may sense an external input applied from the outside. The external input may be a user's input. The user's input may include various types of external inputs such as a portion of a user's body, light, heat, a pen, or pressure.

The input sensing layer ISL may be formed on the display panel DP through a continuous process. For example, the input sensing layer ISL may be disposed directly on the display panel DP. The expression “directly disposed” may mean that a third component is not disposed between the input sensing layer ISL and the display panel DP. For example, a separate adhesive member may not be disposed between the input sensing layer ISL and the display panel DP. For example, the input sensing layer ISL may be directly disposed on the encapsulation layer TFL.

However, embodiments are not limited thereto, and an adhesive member (not shown) may be further disposed between the input sensing layer ISL and the display panel DP. The input sensing layer ISL may include a lower insulating layer IS-IL1, a first conductive layer IS-CL1, an interlayer insulating layer IS-IL2, a second conductive layer IS-CL2, and an upper insulating layer IS-IL3. In an embodiment, at least one of the lower insulating layer IS-IL1 and the upper insulating layer IS-IL3 may be omitted.

The first conductive layer IS-CL1 and the second conductive layer IS-CL2 may each have a single-layered structure or may each have a multi-layered structure stacked in the third directional DR3. A conductive layer having a multi-layered structure may include at least two transparent conductive layers or metal layers. A conductive layer having a multi-layered structure may include metal layers that include metals that are different from each other. The transparent conductive layers may include indium tin oxide (ITO), indium zinc oxide (IZO), zinc oxide (ZnO), indium tin zinc oxide (ITZO), PEDOT, a metal nano wire, or graphene. The metal layer may include molybdenum, silver, titanium, copper, aluminum, or an alloy thereof. For example, the first and second conductive layers IS-CL1 and IS-CL2 may each have a three-layered metal structure. For example, the first and second conductive layers IS-CL1 and IS-CL2 may each have a three-layered metal structure of titanium/aluminum/titanium. A metal having relatively high durability and low reflectivity may be applied to an upper layer or a lower layer, and a metal having high electrical conductivity may be applied to an inner layer.

The first conductive layer IS-CL1 and the second conductive layer IS-CL2 may each include conductive patterns. Hereinafter, it will be described that the first conductive layer IS-CL1 includes first conductive patterns and the second conductive layer IS-CL2 includes second conductive patterns. The first conductive patterns and the second conductive patterns may each include sensing electrodes and signal lines connected to the sensing electrodes. The first conductive patterns and the second conductive patterns may be disposed to overlap a light shielding part BM, which will be described later. The light shielding part BM overlaps the first conductive layer IS-CL1 and the second conductive layer IS-CL2 to prevent the reflection of external light by the first conductive layer IS-CL1 and the second conductive layer IS-CL2.

The lower insulating layer IS-IL1, the interlayer insulating layer IS-IL2, and the upper insulating layer IS-IL3 may each include an inorganic film or an organic film. In an embodiment, the lower insulating layer IS-IL1 and the interlayer insulating layer IS-IL2 may include inorganic films. In an embodiment, the upper insulating layer IS-IL3 may include an organic film.

In an embodiment, the display module DM may include the anti-reflection member RP disposed on the display panel DP. In an embodiment, the anti-reflection member RP may be directly disposed on the input sensing layer ISL. The anti-reflection member RP may include a color filter layer CFL and an organic planarization layer OCL.

The color filter layer CFL may include filter parts CF and the light shielding part BM. The filter parts CF may include a red filter part CF-R, a green filter part CF-G, and a blue filter part CF-B. The red filter part CF-R, the green filter part CF-G, and the blue filter part CF-B may be disposed to respectively correspond to the red light emitting region PXA-R, the green light emitting region PXA-G, and the blue light emitting region PXA-B. The green filter part CF-G may overlap the light sensing region IPA. For example, in an embodiment, the green filter part CF-G may overlap the green light emitting element ED-G and the light sensing element OPD.

The red filter part CF-R may transmit red light, the green filter part CF-G may transmit green light, and the blue filter part CF-B may transmit blue light. The red filter part CF-R, the green filter part CF-G, and the blue filter part CF-B may each include a polymeric photosensitive resin and a pigment or dye. The red filter part CF-R may include a red pigment or dye, the green filter part CF-G may include a green pigment or dye, and the blue filter part CF-B may include a blue pigment or dye.

However, embodiments are not limited thereto, and the blue filter part CF-B may not include a pigment or dye. The blue filter part CF-B may include a polymeric photosensitive resin and may not include a pigment or dye. The blue filter part CF-B may be transparent. The blue filter part CF-B may be formed of a transparent polymeric photosensitive resin.

The light shielding part BM may be disposed on the input sensing layer ISL and may overlap the boundary of the neighboring filter parts CF. The edges of neighboring filter parts CF may overlap each other. For example, the green filter part CF-G and the red filter part CF-R may be disposed on the light shielding part BM to overlap each other, or the green filter part CF-G and the blue filter part CF-B may be disposed on the light shielding part BM to overlap each other. The light shielding part BM may prevent light leakage and may separate boundaries between the adjacent color filter parts CF-R, CF-G, and CF-B.

The light shielding part BM may be a black matrix. The light shielding part BM may include an organic pigment or dye. The light shielding part BM may include an organic light shielding material or an inorganic light shielding material containing a black pigment or dye. The light shielding part BM may overlap the pixel defining film PDL. The light shielding part BM may overlap the pixel defining film PDL that separates the light emitting regions PXA-R, PXA-G, and PXA-B, and the light sensing regions IPA from each other.

The organic planarization layer OCL may be disposed on the color filter layer CFL. The organic planarization layer OCL may be disposed on the color filter layer CFL to protect the color filter parts CF-R, CF-G, and CF-B and to planarize the upper surface of the anti-reflection member RP. The organic planarization layer OCL may include an organic material such as an acrylic-based resin or an epoxy resin.

FIG. 6 is a schematic cross-sectional view of a portion of the electronic device according to an embodiment. FIG. 6 illustrates the light emitting element and the light sensing element in operation.

Referring to FIG. 6, in the electronic device ED according to an embodiment, a light OT-L emitted from a green light emitting element ED-G included in the display element layer EDL may be reflected by an external object (e.g., a finger) as an incident reflected light IP-L onto a light sensing element OPD included in the display element layer EDL. The reflected light IP-L that is incident to the light sensing element OPD may be light in a visible light region. The light sensing element OPD may receive incident light such as the reflected light IP-L and may convert the incident light to an electrical signal to change the driving state of the electronic device ED.

For example, the light emitted from the green light emitting element ED-G and reflected from the external object may be incident to the light sensing element OPD, and form the reflected light IP-L, holes and electrons may be separated from each other in the photoelectric conversion layer OPL of the light sensing element OPD, and may be transferred to the first and second electrodes AE and CE. Accordingly, a light signal may be converted to an electrical signal.

In an embodiment, efficiency of the light sensing element OPD in the electronic device ED may be improved because the second electrode CE includes a metal and an organic compound that dopes the metal to facilitate extraction and injection of electrons in the light sensing element OPD.

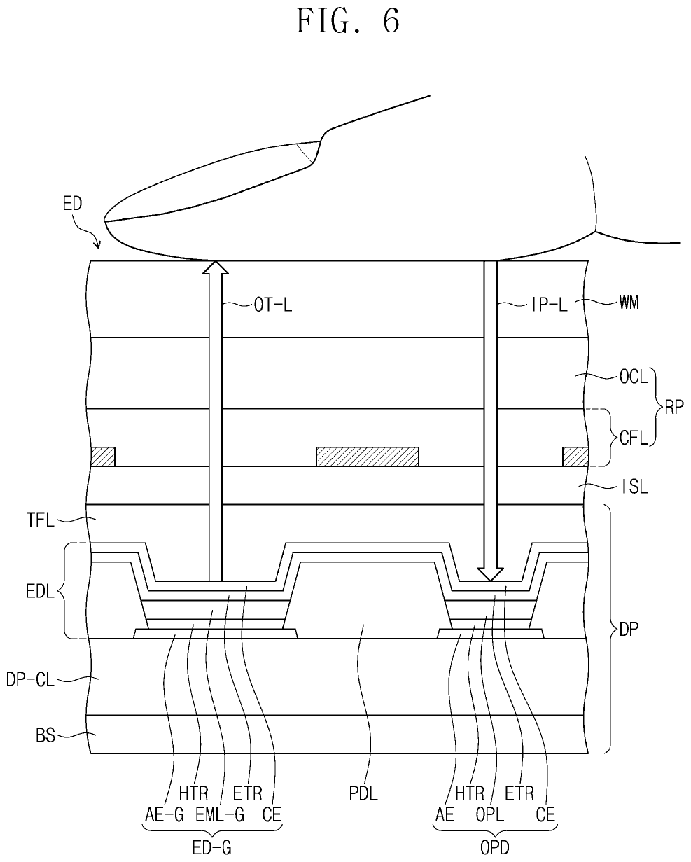

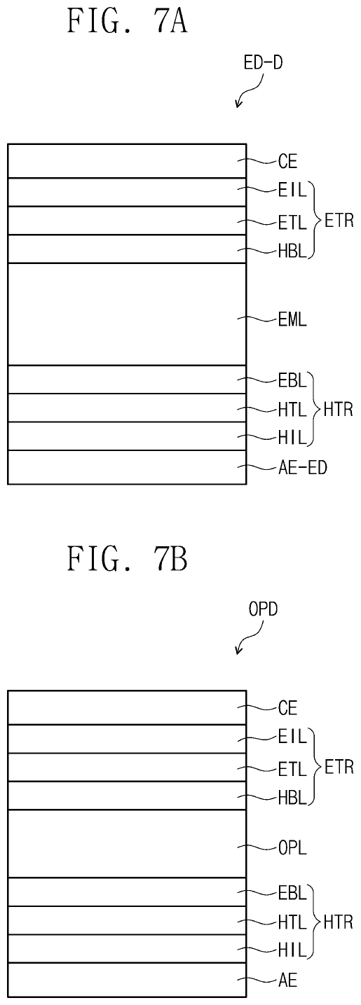

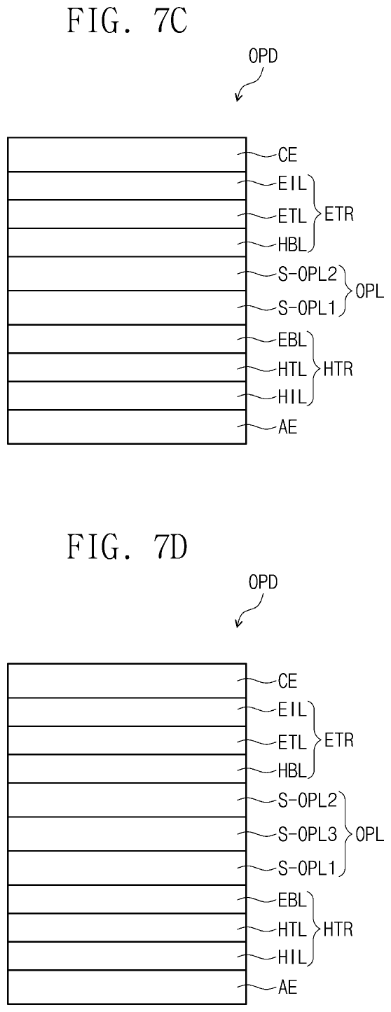

FIGS. 7A to 7D are each a schematic cross-sectional view of a light emitting element and a light sensing element according to an embodiment. FIG. 7A is a schematic cross-sectional view of a light emitting element according to an embodiment, and FIGS. 7B to 7D are each a schematic cross-sectional view of a light sensing element according to an embodiment. In FIG. 7A, the light emitting element ED-D may represent each of the light emitting elements ED-R, ED-G, and ED-B illustrated in FIG. 5. The light emitting elements ED-R, ED-G, and ED-B illustrated in FIG. 5 may each differ from the light emitting element ED-D illustrated in FIG. 7A in the configuration of the emission layer EML.

Referring to FIG. 7A, the light emitting element ED-D according to an embodiment may include a first electrode AE-ED, a hole transport region HTR, an emission layer EML, an electron transport region ETR, and a second electrode CE that are stacked. In the light emitting element ED-D illustrated in FIG. 7A, the first electrode AE-ED, the hole transport region HTR, the emission layer EML, the electron transport region ETR, and the second electrode CE may respectively correspond to the first electrodes AE-R, AE-G, and AE-B, the hole transport region HTR, the emission layers EML-R, EML-G, and EML-B, the electron transport region ETR, and the second electrode CE illustrated in FIG. 5.

The hole transport region HTR may include a hole injection layer HIL, a hole transport layer HTL, and an electron blocking layer EBL that are stacked. However, this is only an example, and the hole transport region HTR may include at least one of the hole injection layer HIL, the hole transport layer HTL, and the electron blocking layer EBL. The electron transport region ETR may include a hole blocking layer HBL, an electron transport layer ETL, and an electron injection layer EIL. However, embodiments are not limited thereto, and the electron transport region ETR may include at least one of the hole blocking layer HBL, the electron transport layer ETL, and the electron injection layer EIL.

Referring to FIGS. 7B to 7D, a light sensing element OPD according to an embodiment may include a first electrode AE, a hole transport region HTR, a photoelectric conversion layer OPL, an electron transport region ETR, and a second electrode CE that are stacked. The hole transport region HTR may include a hole injection layer HIL, a hole transport layer HTL, and an electron blocking layer EBL that are stacked. The electron transport region ETR may include a hole blocking layer HBL, an electron transport layer ETL, and an electron injection layer EIL that are stacked.

In the light emitting element ED-D and the light sensing element OPD illustrated in FIGS. 7A to 7D, the first electrodes AE-ED and AE may each be formed of a metal material, a metal alloy, or a conductive compound. The first electrodes AE-ED and AE may be anodes or cathodes. In an embodiment, the first electrodes AE-ED and AE may be anodes, but embodiments are not limited thereto. For example, the first electrodes AE-ED and AE may be pixel electrodes or sensing electrodes. The first electrodes AE-ED and AE may be transmissive electrodes, transflective electrodes, or reflective electrodes. When the first electrodes AE-ED and AE are transmissive electrodes, the first electrodes AE-ED and AE may include a transparent metal oxide, for example, indium tin oxide (ITO), indium zinc oxide (IZO), zinc oxide (ZnO), or indium tin zinc oxide (ITZO). When the first electrodes AE-ED and AE are transflective electrodes or reflective electrodes, the first electrodes AE-ED and AE may include Ag, Mg, Cu, Al, Pt, Pd, Au, Ni, Nd, Ir, Cr, Li, Ca, LiF/Ca, LiF/Al, Mo, Ti, W, a compound thereof, or a mixture thereof (e.g., a mixture of Ag and Mg).

Referring to FIGS. 7A to 7D, the hole transport region HTR may include a hole injection layer HIL, a hole transport layer HTL, and an electron blocking layer EBL that are stacked. In embodiments, the hole transport region HTR may not include multiple layers, but may be provided as a single layer. In embodiments, the hole transport region HTR may further include at least one of a buffer layer (not shown) or an emission auxiliary layer (not shown).

The hole transport region HTR may include WO₃, a phthalocyanine compound such as copper phthalocyanine, N′,N′″-([1,l′-biphenyl]-4,4′-diyl) bis (N′-phenyl-N⁴,N⁴-di-m-tolylbenzene-1,4-diamine) (DNTPD), 4,4′,4″-[tris (3-methylphenyl) phenylamino]triphenylamine (m-MTDATA), 4,4′,4″-tris (N,N-diphenylamino) triphenylamine (TDATA), 4,4′,4″-tris [N-(2-naphthyl)-N-phenylamino]-triphenylamine (2-TNATA), poly (3,4-ethylenedioxythiophene)/poly (4-styrenesulfonate) (PEDOT/PSS), polyaniline/dodecylbenzenesulfonic acid (PANI/DBSA), polyaniline/camphor sulfonic acid (PANI/CSA), polyaniline/poly (4-styrenesulfonate) (PANI/PSS), N,N′-di (naphthalene-1-yl)-N,N′-diphenyl-benzidine (NPB (or NPD)), triphenylamine-containing polyetherketone (TPAPEK), 4-isopropyl-4′-methyldiphenyliodonium [tetrakis (pentafluorophenyl) borate], dipyrazino [2,3-f: 2′,3′-h]quinoxaline-2,3,6,7,10,11-hexacarbonitrile (HAT-CN), etc.

The hole transport region HTR may include 9-(4-tert-butylphenyl)-3,6-bis (triphenylsilyl)-9H-carbazole (CzSi), 9-phenyl-9H-3,9′-bicarbazole (CCP), 1,3-bis (1,8-dimethyl-9H-carbazol-9-yl) benzene (mDCP), etc.

The hole transport region HTR may include the above-described compounds of the hole transport region HTR in at least one of a hole injection layer HIL, a hole transport layer HTL, and an electron blocking layer EBL.

However, embodiments are not limited thereto, and the hole injection layer HIL, the hole transport layer HTL, and/or the electron blocking layer EBL may include a material of the related art from which hole transport properties may be obtained without a substantial increase in driving voltage, in addition to the above-described materials.

In the light emitting element ED-D, the emission layer EML may be provided on the hole transport region HTR. The emission layer EML may be a layer consisting of a single material, a layer including different materials, or a structure including multiple layers including different materials.

In the light emitting element ED-D according to an embodiment, the emission layer EML may include an organic light emitting material or a quantum dot material. For example, the emission layer EML may include anthracene derivatives, pyrene derivatives, fluoranthene derivatives, chrysene derivatives, dihydrobenzanthracene derivatives, or triphenylene derivatives as an organic luminescent material.

In the light emitting element ED-D according to an embodiment, the emission layer EML may include a host and a dopant. The emission layer EML may include, as a dopant material, an organic fluorescence dopant material, an organic phosphorescence dopant material, a thermally activated delayed fluorescence dopant material, an organometallic complex as a phosphorescence dopant material, or the like.

The emission layer EML may include, as a host material, at least one of bis [2-(diphenylphosphino) phenyl]ether oxide (DPEPO), 4,4′-bis (carbazol-9-yl) biphenyl (CBP), 1,3-bis (carbazol-9-yl) benzene (mCP), 2,8-bis (diphenylphosphoryl) dibenzo[b,d]furan (PPF), 4,4′,4″-tris (carbazol-9-yl)-triphenylamine (TCTA), or 1,3,5-tris (1-phenyl-1H-benzo[d]imidazole-2-yl) benzene (TPBi). However, embodiments are not limited thereto. For example, tris (8-hydroxyquinolino) aluminum (Alq₃), 4,4′-bis (N-carbazolyl)-1,l′-biphenyl (CBP), poly (N-vinylcarbazole) (PVK), 9,10-di (naphthalene-2-yl) anthracene (ADN), 4,4′,4″-tris (carbazol-9-yl) triphenylamine (TCTA), 1,3,5-tris (N-phenylbenzimidazole-2-yl) benzene (TPBi), 2-tert-butyl-9,10-di (naphth-2-yl) anthracene (TBADN), distyrylarylene (DSA), 4,4′-bis (9-carbazolyl)-2,2′-dimethyl-biphenyl (CDBP), 2-methyl-9,10-bis (naphthalen-2-yl) anthracene (MADN), hexaphenylcyclotriphosphazene (CP1), 1,4-bis (triphenylsilyl) benzene (UGH2), hexaphenylcyclotrisiloxane (DPSiO₃), octaphenylcyclotetra siloxane (DPSiO₄), 2,8-bis (diphenylphosphoryl) dibenzofuran (PPF), etc. may be used as a host material.

In an embodiment, the emission layer EML may include, as a dopant material of the related art, a styryl derivative (e.g., 1,4-bis [2-(3-N-ethylcarbazoryl) vinyl|benzene (BCzVB), 4-(di-p-tolylamino)-4′-[(di-p-tolylamino) styryl]stilbene (DPAVB), and N-(4-((E)-2-(6-((E)-4-(diphenylamino) styryl) naphthalen-2-yl) vinyl) phenyl)-N-phenylbenzenamine (N-BDAVBi)), perylene or a derivative thereof (e.g., 2,5,8,11-tetra-t-butylperylene (TBP)), pyrene or a derivative thereof (e.g., 1,1′-dipyrene, 1,4-dipyrenylbenzene, 1,4-bis (N,N-diphenylamino) pyrene), etc.

For example, the emission layer EML may include, as a phosphorescence dopant, a metal complex including iridium (Ir), platinum (Pt), osmium (Os), gold (Au), titanium (Ti), zirconium (Zr), hafnium (Hf), curopium (Eu), terbium (Tb), or thulium (Tm). For example, iridium (III) bis (4,6-difluorophenylpyridinato-N,C2) picolinato (FIrpic), bis (2,4-difluorophenylpyridinato)-tetrakis (1-pyrazolyl) borate iridium (III) (Flr6), or platinum octaethyl porphyrin (PtOEP) may be used as a phosphorescent dopant material. However, embodiments are not limited thereto.

Referring to FIGS. 7B to 7D, the light sensing element OPD includes the photoelectric conversion layer OPL disposed on the hole transport region HTR. The photoelectric conversion layer OPL may include a light-receiving material that receives and converts light into an electrical signal.

The photoelectric conversion layer OPL may include an organic light-receiving material as the light-receiving material. In an embodiment, the photoelectric conversion layer OPL may include at least one of an electron donor compound and an electron acceptor compound. For example, the photoelectric conversion layer OPL according to an embodiment may include, as an electron acceptor compound, compound D-1

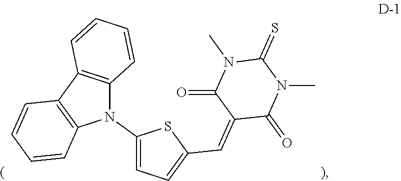 [SMILES: CN1C(=O)C(=Cc2ccc(-n3c4ccccc4c4ccccc43)s2)C(=O)N(C)C1=S]

a fullerene derivative, a perylene tetracarboxylic diimide (PTCDI) derivative, a perylene tetracarboxylic dianhydride (PTCDA) derivative, a 1,4,5,8-naphthalenetetracarboxylic dianhydride (NTCDA) derivative, or a naphthalenetetracarboxylic diimide (NTCDI) derivative. The photoelectric conversion layer OPL according to an embodiment may include, as an electron donor compound, a phthalocyanine-based compound, a perylene-based compound, a squaraine dye compound, or the like. For example, in an embodiment, the photoelectric conversion layer OPL may include, as an electron donor compound, subphthalocyanine (SubPc), zinc phthalocyanine (ZnPc), ditolyaminothienyl-benzothiadiazole-dicyanovinylene (DTDCTB), lead phthalocyanine (PbPc), 5,10,15,20-tetraphenyl bisbenz [5,6]indeno[1,2,3-cd: 1′,2′,3′-1m]perylene (DBP), copper phthalocyanine (CuPc), or the like. The photoelectric conversion layer OPL according to an embodiment may include an electron donor compound and an electron acceptor compound.

In the light sensing element OPD according to an embodiment, the photoelectric conversion layer OPL may include an organic polymer material or the like as a light-receiving material. For example, the photoelectric conversion layer OPL may include a conjugated polymer. The photoelectric conversion layer OPL may include a thiophene-based conjugated polymer, a benzodithiophene-based conjugated polymer, a thieno [3,4-c]pyrrole-4,6-dione (TPD)-based conjugated polymer, a diketo-pyrrole-pyrrole (DPP)-based conjugated polymer, a benzothiadiazole (BT)-based conjugated polymer, or the like. However, embodiments are not limited thereto.

Referring to FIGS. 7C and 7D, the photoelectric conversion layer OPL may include multiple sub-photoelectric conversion layers S-OPL1, S-OPL2, and S-OPL3. For example, the photoelectric conversion layer OPL may include a first sub-photoelectric conversion layer S-OPL1 and a second sub-photoelectric conversion layer S-OPL2, or may include a first sub-photoelectric conversion layer S-OPL1, a second sub-photoelectric conversion layer S-OPL2, and a third sub-photoelectric conversion layer S-OPL3.

In an embodiment, the first sub-photoelectric conversion layer S-OPL1 may include an electron donor compound and may not include an electron acceptor compound. The second sub-photoelectric conversion layer S-OPL2 may not include an electron donor compound and may include an electron acceptor compound. The third sub-photoelectric conversion layer S-OPL3 may include both an electron donor compound and an electron acceptor compound.

For example, when the photoelectric conversion layer OPL includes a first sub-photoelectric conversion layer S-OPL1 and a second sub-photoelectric conversion layer S-OPL2, as illustrated in FIG. 7C, the first sub-photoelectric conversion layer S-OPL1 may be disposed on the hole transport region HTR, and the second sub-photoelectric conversion layer S-OPL2 may be disposed between the first sub-photoelectric conversion layer S-OPL1 and the electron transport region ETR. When the photoelectric conversion layer OPL includes a first sub-photoelectric conversion layer S-OPL1, a second sub-photoelectric conversion layer S-OPL2, and a third sub-photoelectric conversion layer S-OPL3, the first sub-photoelectric conversion layer S-OPL1, the third sub-photoelectric conversion layer S-OPL3, and the second sub-photoelectric conversion layer S-OPL2 may be stacked in the stated order between the hole transport region HTR and the electron transport region ETR, as illustrated in FIG. 7D. However, this is merely an example, and embodiments are not limited thereto. Thus, the stacking order of the first to third sub-photoelectric conversion layers S-OPL1, S-OPL2, and S-OPL3 may be changed.

Referring to FIGS. 7A to 7D again, the electron transport region ETR may include an electron transport layer ETL, an electron injection layer EIL, and a hole blocking layer HBL that are stacked. However, embodiments are not limited thereto, and the electron transport region ETR may have a single-layered structure.

The electron transport region ETR may include an anthracene-based compound. However, embodiments are not limited thereto, and the electron transport region ETR may include, for example, tris (8-hydroxyquinolinato) aluminum (Alq₃), 1,3,5-tri [(3-pyridyl)-phen-3-yl]benzene, 2,4,6-tris (3′-(pyridin-3-yl) biphenyl-3-yl)-1,3,5-triazine, 2-(4-(N-phenylbenzoimidazol-1-yl) phenyl)-9,10-dinaphthylanthracene, 1,3,5-tri (1-phenyl-1H-benzo[d]imidazol-2-yl) benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis (2-methyl-8-quinolinolato-N1,08)-(1,1′-biphenyl-4-olato) aluminum (BAlq), beryllium bis (benzoquinolin-10-olate) (Bebq2), 9,10-di (naphthalene-2-yl) anthracene (ADN), 1,3-bis [3,5-di (pyridin-3-yl) phenyl]benzene (BmPyPhB), diphenyl (4-(triphenylsilyl) phenyl) phosphine oxide (TSPO1), or a mixture thereof.

In an embodiment, the electron transport region ETR may include a triazine-based compound. For example, the hole blocking layer HBL and the electron transport layer ETL may each include a triazine-based compound having a lowest unoccupied molecular orbital (LUMO) energy level in a range of about 2.0 eV to about 2.5 eV, and a highest occupied molecular orbital (HOMO) energy level in a range of about 5.0 eV to about 7.0 eV.

In an embodiment, the hole blocking layer HBL and the electron transport layer ETL may each include a 1,3,5-triazine compound represented by Formula ET-1:

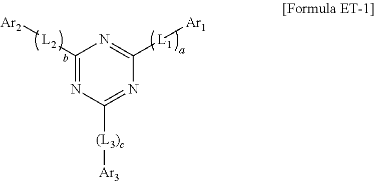

In Formula ET-1, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, L₁ to L₃ may each independently be a substituted or unsubstituted arylene group having 6 to 30 ring-forming carbon atoms or a substituted or unsubstituted heteroarylene group having 2 to 30 ring-forming carbon atoms.

In an embodiment, the hole blocking layer HBL and the electron transport layer ETL may each independently include at least one of Compound ET31 to Compound ET37. However, this is merely an example, and embodiments are not limited thereto.

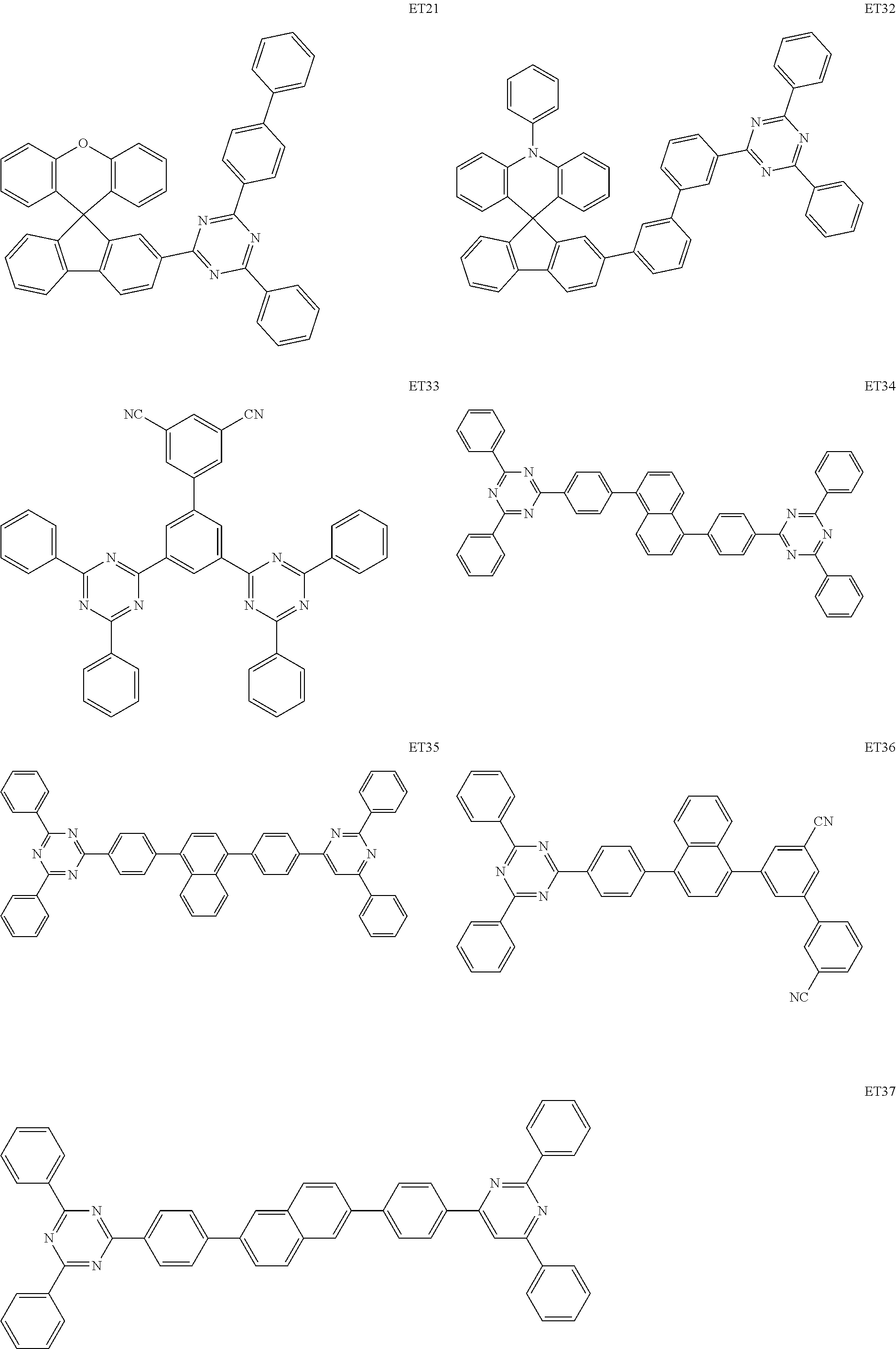

In an embodiment, the electron transport region ETR may include: a metal halide such as LiF, NaCl, CsF, RbCI, RbI, Cul, and KI; a lanthanide metal such as Yb; or a co-deposited material of a metal halide and a lanthanide metal. For example, the electron transport region ETR may include KI: Yb, RbI: Yb, LiF: Yb, etc., as a co-deposited material. The electron transport region ETR may include Rb₂CO₃. The electron transport region ETR may be formed of a metal oxide such as Li₂O or BaO, or 8-hydroxyl-lithium quinolate (Liq), etc., but embodiments are not limited thereto. The electron transport region ETR may also be formed of a mixture material of an electron transport material and an insulating organometallic salt. The insulating organometallic salt may be a material having an energy band gap equal to or greater than about 4 eV. For example, the insulating organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl (4-(triphenylsilyl) phenyl) phosphine oxide (TSPO1), and 4,7-diphenyl-1,10-phenanthroline (Bphen) in addition to the above-described materials, but embodiments are not limited thereto.

The electron transport region ETR may include the above-described compounds of the electron transport region ETR in at least one of the electron injection layer EIL, the electron transport layer ETL, and the hole blocking layer HBL.

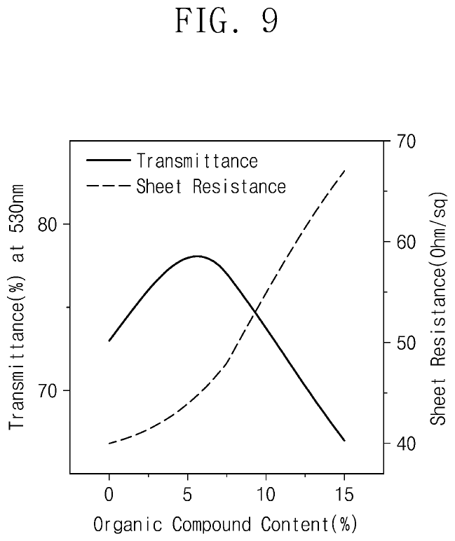

FIG. 8A is a schematic perspective view of a second electrode according to an embodiment. FIG. 8B is a schematic cross-sectional view of the second electrode according to an embodiment. FIG. 9 is a graph showing the evaluation results of transmittance and sheet resistance of the light sensing element according to an embodiment. In FIG. 9, the transmittance is a result measured by using a UV-Vis spectrophotometer, and the sheet resistance is a result measured by using a 4-point probe.

Referring to FIGS. 7A to 7D, and FIGS. 8A and 8B, the second electrode CE is provided on the electron transport region ETR. The second electrode CE may be a common electrode. The second electrode CE may be a cathode or an anode. For example, when the first electrodes AE-ED and AE are anodes, the second electrode CE may be a cathode, and when the first electrodes AE-ED and AE are cathodes, the second electrode CE may be an anode. In the specification, the second electrode CE may be referred to as a transparent electrode.

In an embodiment, the second electrode CE may be a cathode that is an electron injection electrode. For example, the second electrode CE may include a metal having a low work function. The second electrode CE may include a metal having a work function equal to or greater than about 3.0 eV. For example, the second electrode CE may include at least one of calcium (Ca), magnesium (Mg), aluminum (Al), silver (Ag), gold (Au), zinc (Zn), and copper (Cu). For example, the second electrode CE may include Ca, Mg, Al, Ag, Au, Zn, Cu, a compound thereof, or a mixture thereof. In an embodiment, the metal included in the second electrode CE is not limited to the above-described materials, and may include any metal material having a work function equal to or greater than about 3.0 eV, in addition to the above-described materials.

The second electrode CE according to an embodiment may be formed of a layer including a metal and an organic compound. The second electrode CE may have a single-layered structure that is formed by co-depositing a metal and an organic compound. The second electrode CE according to an embodiment may be a layer in which the metal is doped with an organic compound. The second electrode CE may be formed by doping the metal with an organic compound having a lowest unoccupied molecular orbital (LUMO) energy level in a range of about 2.0 eV to about 3.0 eV. For example, the second electrode CE may be a layer in which Ca, Mg, Al, Ag, Au, Zn, Cu, a compound thereof, a or mixture thereof is doped with an organic compound having a LUMO energy level in a range of about 2.0 eV to about 3.0 eV. In the specification, the term “LUMO energy level” refers to a distance from a vacuum level to a lowest unoccupied molecular orbital, and even when an energy level is displayed in a negative (−) direction from the vacuum level, the energy level is interpreted to mean an absolute value of the corresponding energy value.

In an embodiment, the organic compound included in the second electrode CE may include at least one of a triazine-based compound, a phosphine oxide-based compound, and a phenanthroline-based compound. For example, the triazine-based compound may be a compound containing a naphthyl group and/or a fluorenyl group. In an embodiment, the triazine-based compound may be represented by Formula A or Formula B:

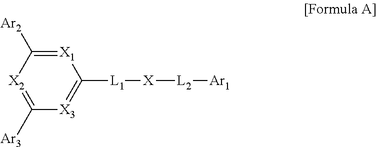

In Formula A, X may be a substituted or unsubstituted divalent naphthylene group. For example, X may be a naphthylene group represented by one of Substituents X-1 to X-4:

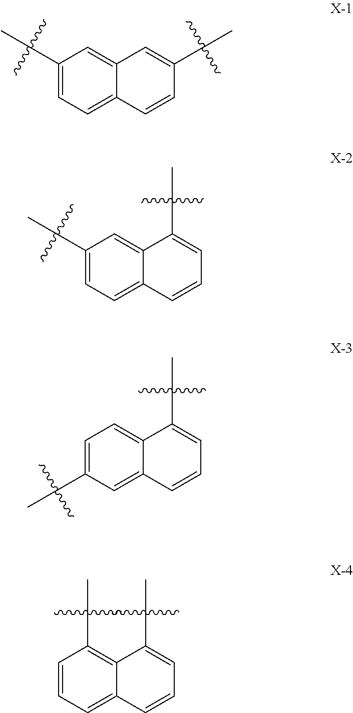

In Formula A, L₁ and L₂ may each independently be a direct linkage, a substituted or unsubstituted arylene group having 3 to 30 ring-forming carbon atoms, or a substituted or unsubstituted alkenylene group having 2 to 30 carbon atoms.

In Formula A, Ar₁ may be a substituted or unsubstituted aryl group having 3 to 30 ring-forming carbon atoms, or a substituted or unsubstituted heterocyclic group having 2 to 30 ring-forming carbon atoms.

In Formula A, X₁ to X₃ may each independently be N or CH, and at least one of X₁ to X₃ may each be N.

In Formula A, Ar₂ and Ar₃ may each independently be a substituted or unsubstituted aryl group having 3 to 30 ring-forming carbon atoms or a substituted or unsubstituted heterocyclic group having 2 to 30 ring-forming carbon atoms.

For example, when Ar₁ to Ar₃ are each a heterocyclic group, Ar₁ to Ar₃ may each include at least one of O, N, and S as a heteroatom. When Ar₁ to Ar₃ are each a substituted aryl group, Ar₁ to Ar₃ may each be an aryl group substituted with at least one substituent selected from the group consisting of a deuterium atom, an alkyl group, an alkenyl group, a cycloalkyl group, an aryl group, an arylalkyl group, an arylalkenyl group, and a heterocyclic group. When Ar₁ to Ar₃ are each a substituted heterocyclic group, Ar₁ to Ar₃ may each be a heterocyclic group substituted with at least one substituent selected from the group consisting of a deuterium atom, an alkyl group, an alkenyl group, a cycloalkyl group, an aryl group, an arylalkyl group, an arylalkenyl group, and a heterocyclic group.

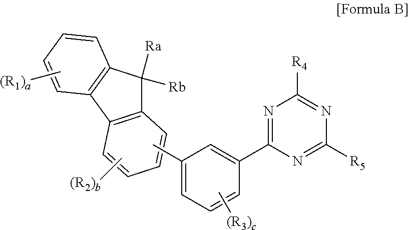

In Formula B, Ra and Rb may each independently be a substituted or unsubstituted methyl group. In Formula B, R₁ and R₂ may each independently be a hydrogen atom, a substituted or unsubstituted alkyl group having 1 to 40 carbon atoms, or bonded to an adjacent group to form a ring.

In Formula B, R₃ may be a hydrogen atom or a deuterium atom, and R₄ and R₅ may each independently be a substituted or unsubstituted aryl group having 6 to 30 ring-forming carbon atoms.

In Formula B, a and c may each independently be an integer from 0 to 4, and b may be an integer from 0 to 3. In Formula B, if a, b, and c are each 0, Formula B may not be substituted with each of R₁, R₂, and R₃. A case where a is 4 and four R₁ groups are all hydrogen atoms may be the same as a case where a is 0. If a is 2 or greater, multiple R₁ groups may all be the same, or at least one thereof may be different from the remainder. A case where b is 3 and three R₂ groups are all hydrogen atoms may be the same as a case where b is 0. If b is 2 or greater, multiple R₂ groups may all be the same, or at least one thereof may be different from the remainder. A case where c is 4 and four R₃ groups are all hydrogen atoms may be the same as a case where c is 0. If c is 2 or greater, multiple R₃ groups may all be the same, or at least one thereof may be different from the remainder.

In an embodiment, in Formula B, when Ra, Rb, R₁, R₂, R₄, and R₅ are each substituted, Ra, Rb, R₁, R₂, R₄, and R₅ may each independently be substituted with at least one substituent selected from the group consisting of a deuterium atom, a halogen atom, a cyano group, a nitro group, an amine group, an alkyl group having 1 to 40 carbon atoms, and an aryl group having 6 to 30 ring-forming carbon atoms, but embodiments are not limited thereto.

In an embodiment, the phosphine oxide-based compound may be represented by Formula C:

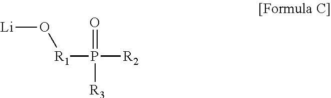

In Formula C, R₁ may be a substituted or unsubstituted arylene group having 6 to 30 ring-forming carbon atoms or a substituted or unsubstituted heteroarylene group having 2 to 30 ring-forming carbon atoms. In Formula C, R₂ and R₃ may each independently be a substituted or unsubstituted aryl group having 6 to 30 ring-forming carbon atoms or a substituted or unsubstituted heteroaryl group having 2 to 30 ring-forming carbon atoms.

In an embodiment, R₁ may be a substituted or unsubstituted heteroarylene group having 2 to 30 ring-forming carbon atoms. In an embodiment, at least one of R₂ and R₃ may be a substituted or unsubstituted heteroaryl group having 2 to 30 ring-forming carbon atoms, but embodiments are not limited thereto.

In an embodiment, the phenanthroline-based compound may be represented by Formula D:

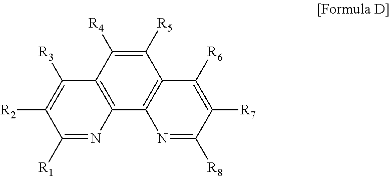

In Formula D, R₁ to R₈ may each independently be a hydrogen atom, a deuterium atom, a substituted or unsubstituted alkyl group having 1 to 20 carbon atoms, or a substituted or unsubstituted aryl group having 3 to 30 ring-forming carbon atoms. In an embodiment, at least one of R₁ to R₈ may be a substituted or unsubstituted aryl group having 3 to 30 ring-forming carbon atoms.

In an embodiment, the organic compound may include at least one compound selected from Compound Group 1:

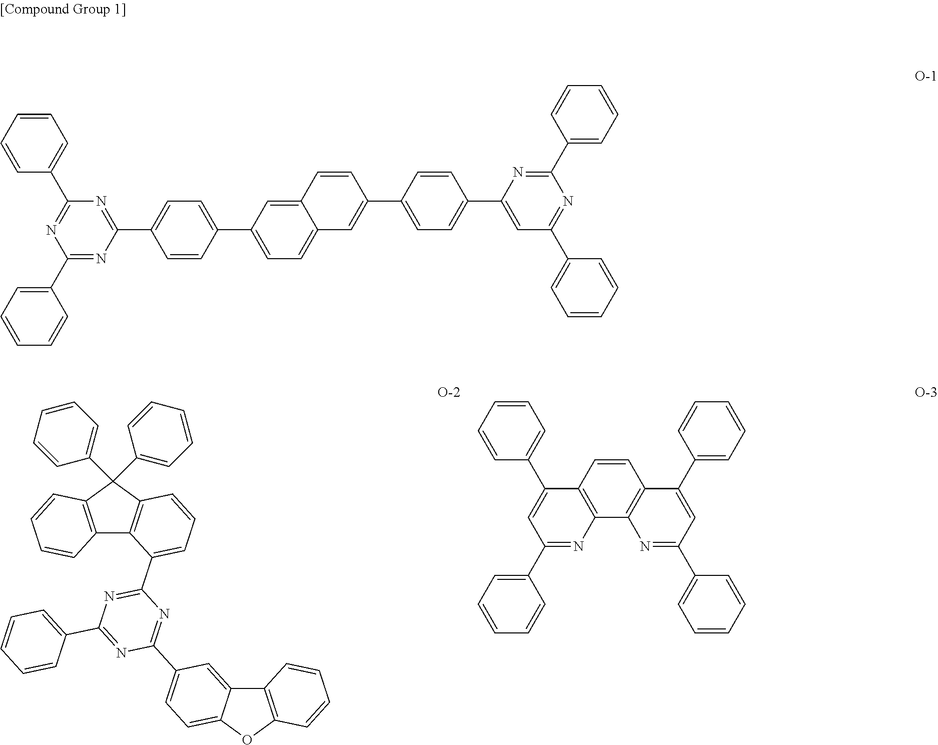 [SMILES: c1ccc(-c2cc(-c3ccc(-c4ccc5cc(-c6ccc(-c7nc(-c8ccccc8)nc(-c8ccccc8)n7)cc6)ccc5c4)cc3)nc(-c3ccccc3)n2)cc1 ; c1ccc(-c2nc(-c3ccc4oc5ccccc5c4c3)nc(-c3cccc4c3-c3ccccc3C4(c3ccccc3)c3ccccc3)n2)cc1 ; c1ccc(-c2cc(-c3ccccc3)c3ccc4c(-c5ccccc5)cc(-c5ccccc5)nc4c3n2)cc1]

According to an embodiment, a doping concentration of the organic compound in the second electrode CE in which the metal is doped with the organic compound may be in a range of about 0.5% to about 10%. The doping concentration of the organic compound may be an amount of the organic compound based on a total weight of the metal and the organic compound. Referring to FIG. 9, it may be seen that the second electrode CE according to an embodiment has excellent transmittance and low sheet resistance when the doping concentration of the organic compound is in a range of about 0.5% to about 10%. In comparison, it may be confirmed that the transmittance of the second electrode CE according to an embodiment decrease when the doping concentration of the organic compound is greater than about 10%.

For example, the doping concentration of the organic compound in the second electrode CE according to an embodiment may be in a range of about 3% to about 7%. For example, the doping concentration of the organic compound may be about 5%. When the doping concentration of the organic compound in the metal is within any of the ranges above, the second electrode CE may have excellent transmittance and low resistance. Accordingly, the electronic device ED according to an embodiment may include the second electrode CE in which the metal is doped with the organic compound in a specific range, thereby improving photoelectric conversion efficiency.

The second electrode CE according to an embodiment may be provided through a thermal deposition process. When the metal and the organic compound are co-deposited by a thermal deposition process, the metal may form nanoparticles to increase its own size and form a cluster (for example, a nucleus). The organic compound may also form a cluster. When a large amount of metal is included in the process, the second electrode CE in a thin film state may be provided as the metal nucleus gradually grows. Nuclei of metals in various sizes may be formed according to a ratio of the metal and the organic compound. For example, when the second electrode CE is doped with the organic compound in the above range, a content of the metal included in the second electrode CE is reduced, thereby suppressing the bulk characteristic of metal agglomeration, and thus metal nanoparticles P1 may be included in the second electrode CE. The metal nanoparticles P1 may have various light absorption and reflection characteristics in the visible light region due to a surface plasmon effect.

Referring to FIGS. 8A and 8B, the second electrode CE according to an embodiment may include a metal nanostructure NW in which metal nanoparticles P1 are connected. The metal nanostructure NW may be in the form of a nanowire in which the metal nanoparticles P1 are connected. For example, the second electrode CE may include the metal nanostructure NW in which nanowires including the metal nanoparticles P1 are connected to each other to form multiple intersections. For example, the second electrode CE may include metal nanostructures NW in which nanowires are irregularly arranged to be entangled with each other, and may have a structure in which organic compound particles P2 are distributed between the metal nanostructures NW. The second electrode CE may include the metal nanostructure NW in which the metal nanoparticles P1 are connected, thereby securing a smooth charge movement path. Accordingly, the second electrode CE may have a characteristic in which the charges flow readily because electrical resistance is low while maintaining optical transparency.

The electronic device according to an embodiment may include a transparent electrode having low electrical resistance and excellent transmittance, so that photoelectric conversion efficiency may be improved.

Hereinafter, a light sensing element according to an embodiment will be described in detail with reference to the Examples and the Comparative Examples. The Examples described below are only provided as illustrations to assist in understanding the embodiments, and the scope thereof is not limited thereto.

### Examples and Comparative Examples

### 1. Manufacture of Light Sensing Element 1—Examples 1, 4, and 7 to 9, and Comparative Example 1

A glass substrate on which ITO had been patterned was cleaned as a first electrode, and WO₃ (tungsten oxide) was deposited to form a 50 Å-thick hole injection layer. NPB was deposited to form a 300 Å-thick hole transport layer.

A photoelectric conversion layer was formed on the hole transport layer. A first sub-photoelectric conversion layer including Compound D-1 as an electron donor compound was formed on the hole transport layer, and a second sub-photoelectric conversion layer including perylene tetracarboxylic diimide (PTCDI) as an electron acceptor compound was formed on the first sub-photoelectric conversion layer.

A hole blocking layer and an electron transport layer were sequentially formed on the photoelectric conversion layer. Compound ET31, a triazine-based compound, was deposited to form a 50 Å-thick hole blocking layer, and Rb₂CO₃ doped with Compound ET34 at a doping concentration of about 10% was deposited to form a 300 Å-thick electron transport layer. LiF was deposited to form a 10 Å-thick electron injection layer. Ag, Au, or Cu was doped with an organic compound to form a 1,000 Å-thick second electrode. The types of metals and organic compounds used in forming the second electrodes of Example 1, Example 4, Example 7 to 9, and Comparative Example 1, and the doping concentrations of the organic compounds are shown in Table 1 below.

### 2. Manufacture of Light Sensing Element 2—Examples 2 and 5, and Comparative Example 2

Light sensing element 2 was manufactured in the same manner as Light sensing element 1, except that the photoelectric conversion layer was formed in a single layer on the hole transport layer by using an electron donor compound and an electron acceptor compound.

### 3. Manufacture of Light Sensing Element 3-Examples 3 and 6, and Comparative Example 3

Light sensing element 3 was manufactured in the same manner as Light sensing element 1, except that on the hole transport layer, the first sub-photoelectric conversion layer including an electron donor compound, the third sub-photoelectric conversion layer including an electron donor compound and an electron acceptor compound, and the second sub-photoelectric conversion layer including an electron acceptor compound were sequentially formed.

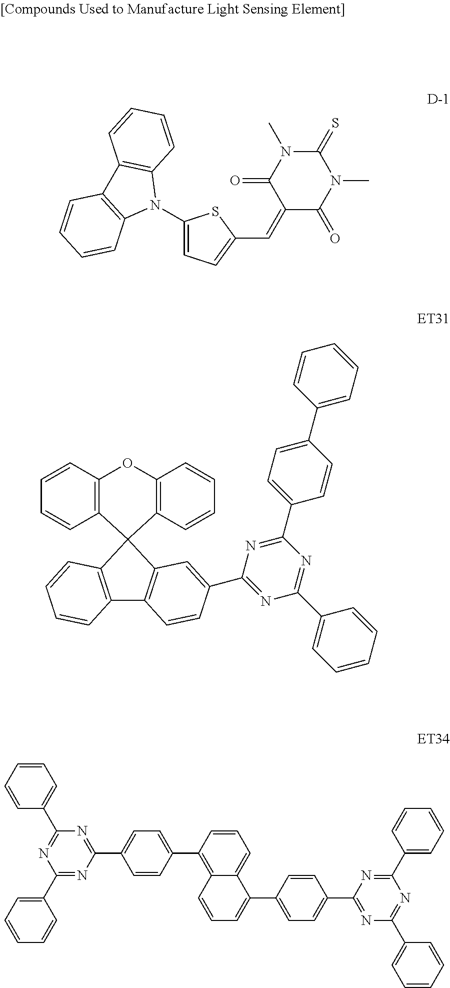 [SMILES: CN1C(=O)C(=Cc2ccc(-n3c4ccccc4c4ccccc43)s2)C(=O)N(C)C1=S ; c1ccc(-c2ccc(-c3nc(-c4ccccc4)nc(-c4ccc5c(c4)C4(c6ccccc6Oc6ccccc64)c4ccccc4-5)n3)cc2)cc1 ; c1ccc(-c2nc(-c3ccccc3)nc(-c3ccc(-c4cccc5c(-c6ccc(-c7nc(-c8ccccc8)nc(-c8ccccc8)n7)cc6)cccc45)cc3)n2)cc1]

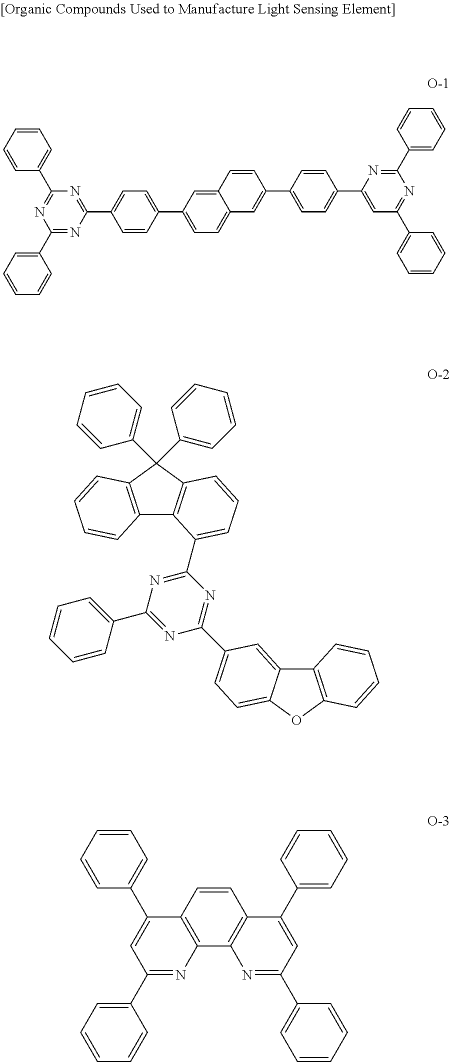 [SMILES: c1ccc(-c2cc(-c3ccc(-c4ccc5cc(-c6ccc(-c7nc(-c8ccccc8)nc(-c8ccccc8)n7)cc6)ccc5c4)cc3)nc(-c3ccccc3)n2)cc1 ; c1ccc(-c2nc(-c3ccc4oc5ccccc5c4c3)nc(-c3cccc4c3-c3ccccc3C4(c3ccccc3)c3ccccc3)n2)cc1 ; c1ccc(-c2cc(-c3ccccc3)c3ccc4c(-c5ccccc5)cc(-c5ccccc5)nc4c3n2)cc1]

### 4. Evaluation of Light Sensing Element Characteristics

Results of evaluating efficiencies of the light sensing elements in Examples 1 to 9 and Comparative Examples 1 to 3 are listed in Table 1. The work function of the metal was measured by ultraviolet photoelectron spectroscopy (UPS). The efficiency (EQEₘₐₓ) of the light sensing element is a photoelectric conversion efficiency, and is shown in Table 1 as a relative efficiency, assuming, as 100%, the case where an entire amount of light is converted into the electrical signal.

TABLE 1

| | | | Doping concentration | Work | LUMO energy | EQEₘₐₓ |
|---|---|---|---|---|---|---|
| | | Organic | of organic compound | function of | level of organic | (%) @ |
| | Metal | Compound | (%) | metal (eV) | compound (eV) | 530 nm |
| Example 1 | Ag | O-1 | 5 | 4.32 | 2.74 | 41 |
| Example 2 | Ag | O-1 | 5 | 4.32 | 2.74 | 16 |
| Example 3 | Ag | O-1 | 5 | 4.32 | 2.74 | 22 |
| Example 4 | Au | O-2 | 5 | 5.1 | 2.77 | 36 |
| Example 5 | Au | O-2 | 5 | 5.1 | 2.77 | 12 |
| Example 6 | Cu | O-3 | 5 | 4.70 | 2.68 | 18 |
| Example 7 | Ag | O-1 | 3 | 4.32 | 2.74 | 35 |
| Example 8 | Ag | O-1 | 7 | 4.32 | 2.74 | 34 |
| Example 9 | Ag | O-1 | 10 | 4.32 | 2.74 | 32 |
| Comparative | Ag | — | 5 | 4.32 | | 32 |
| Example 1 | | | | | | |
| Comparative | Ag | — | 5 | 4.32 | | 11 |
| Example 2 | | | | | | |
| Comparative | Ag | — | 5 | 4.32 | | 15 |
| Example 3 | | | | | | |

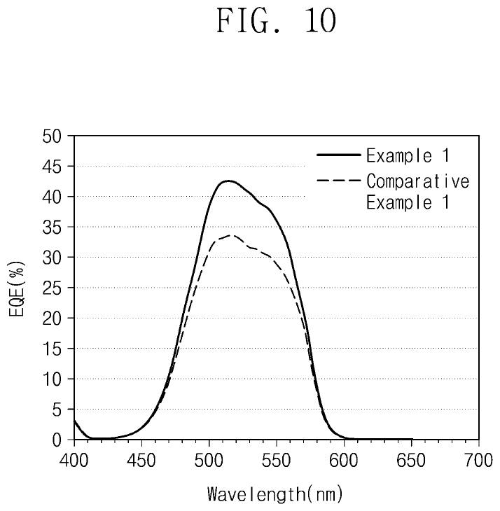

Referring to Table 1 and FIG. 10, it may be confirmed that Examples including the second electrode in which the metal was doped with an organic compound at a doping concentration in a range of about 0.5% to about 10% exhibit excellent light sensing element efficiency as compared with the Comparative Examples which include only the metal.

For example, the light sensing element of Example 1 exhibits an efficiency of about 41%, which is excellent as compared with the light sensing element of Comparative Example 1, which exhibits an efficiency of about 32%.

The electronic device according to an embodiment may include the light sensing element in the display element layer, and the light sensing element may include the second electrode in which the metal is doped with the organic compound at a concentration in a specific range, thereby exhibiting excellent light sensing element characteristics.

An embodiment may provide the electronic device including a transparent electrode having a low electric resistance and an excellent transmittance, thereby improving photoelectric conversion efficiency.

Embodiments have been disclosed herein, and although terms are employed, they are used and are to be interpreted in a generic and descriptive sense only and not for purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. An electronic device comprising:
a display element layer disposed on a base layer and comprising at least one light sensing element, wherein
the light sensing element comprises:
a first electrode;
a hole transport region disposed on the first electrode;
a photoelectric conversion layer disposed on the hole transport region;
an electron transport region disposed on the photoelectric conversion layer; and
a second electrode disposed on the electron transport region,
the second electrode comprises a metal and an organic compound, and
a doping concentration of the organic compound is in a range of about 0.5% to about 10%.

2. The electronic device of claim 1, wherein the metal has a work function greater than or equal to about 3.0 eV.

3. The electronic device of claim 2, wherein the metal comprises at least one of Ca, Mg, Al, Ag, Au, Zn, and Cu.

4. The electronic device of claim 1, wherein the organic compound has a lowest unoccupied molecular orbital (LUMO) energy level in a range of about 2.0 eV to about 3.0 eV.

5. The electronic device of claim 4, wherein the organic compound comprises at least one of a triazine-based compound, a phosphine oxide-based compound, and a phenanthroline-based compound.

6. The electronic device of claim 1, wherein the organic compound comprises at least one compound selected from Compound Group 1:

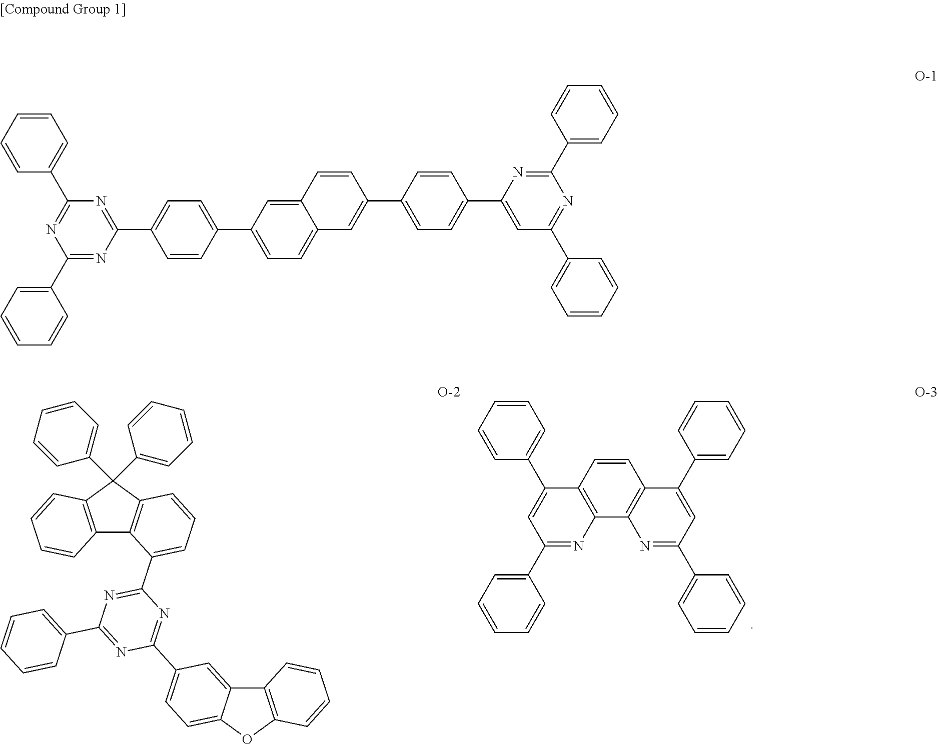 [SMILES: c1ccc(-c2cc(-c3ccc(-c4ccc5cc(-c6ccc(-c7nc(-c8ccccc8)nc(-c8ccccc8)n7)cc6)ccc5c4)cc3)nc(-c3ccccc3)n2)cc1 ; c1ccc(-c2nc(-c3ccc4oc5ccccc5c4c3)nc(-c3cccc4c3-c3ccccc3C4(c3ccccc3)c3ccccc3)n2)cc1 ; c1ccc(-c2cc(-c3ccccc3)c3ccc4c(-c5ccccc5)cc(-c5ccccc5)nc4c3n2)cc1]

7. The electronic device of claim 1, wherein the photoelectric conversion layer comprises at least one of an electron donor compound and an electron acceptor compound.

8. The electronic device of claim 7, wherein the photoelectric conversion layer comprises:
a first sub-photoelectric conversion layer comprising the electron donor compound; and
a second sub-photoelectric conversion layer disposed on the first sub-photoelectric conversion layer and comprising the electron acceptor compound.

9. The electronic device of claim 7, wherein the photoelectric conversion layer comprises the electron donor compound and the electron acceptor compound.

10. The electronic device of claim 7, wherein the photoelectric conversion layer comprises:
a first sub-photoelectric conversion layer including the electron donor compound;
a third sub-photoelectric conversion layer disposed on the first sub-photoelectric conversion layer and comprising the electron donor compound and the electron acceptor compound; and
a second sub-photoelectric conversion layer on the third sub-photoelectric conversion layer and comprising the electron acceptor compound.

11. The electronic device of claim 1, wherein the hole transport region comprises at least one of a hole injection layer, a hole transport layer, or an electron blocking layer.

12. The electronic device of claim 1, wherein the electron transport region comprises at least one of a hole blocking layer, an electron transport layer, and an electron injection layer.

13. An electronic device comprising:
a display element layer disposed on a base layer, wherein
the display element layer comprises:
a pixel defining film in which an opening is defined
a light emitting element; and
a light sensing element,
the light emitting element and the light sensing element are each divided by the pixel defining film,
the light emitting element and the light sensing element each comprises:
a first electrode;
a hole transport region disposed on the first electrode;
an electron transport region disposed on the hole transport region; and
a second electrode disposed on the electron transport region and comprising a metal nanostructure and an organic compound, and
a doping concentration of the organic compound is in a range of about 0.5% to about 10%.

14. The electronic device of claim 13, wherein the metal nanostructure is in a form of a nanowire in which a plurality of metal nanoparticles are connected.

15. The electronic device of claim 14, wherein the plurality of metal nanoparticles have a work function greater than or equal to about 3.0 eV.

16. The electronic device of claim 13, wherein the metal nanostructure comprises at least one of Ca, Mg, Al, Ag, Au, Zn, and Cu.

17. The electronic device of claim 13, wherein the organic compound has a lowest unoccupied molecular orbital (LUMO) energy level in a range of about 2.0 eV to about 3.0 eV.

18. The electronic device of claim 13, wherein the organic compound comprises at least one of a triazine-based compound, a phosphine oxide-based compound, and a phenanthroline-based compound.

19. The electronic device of claim 13, wherein
the light emitting element comprises an emission layer disposed between the hole transport region and the electron transport region,
the light sensing element comprises a photoelectric conversion layer disposed between the hole transport region and the electron transport region, and
the photoelectric conversion layer converts incident light to an electrical signal.

20. The electronic device of claim 19, wherein the photoelectric conversion layer comprises at least one of an electron donor compound and an electron acceptor compound.
